(19) United States
(12) Patent Application Publication
(10) Pub. No.: US 2026/0123245 A1
(43) Pub. Date: Apr. 30, 2026

(54) DISPLAY DEVICE AND ELECTRONIC DEVICE INCLUDING DISPLAY DEVICE

(71) Applicant: Samsung Display Co., Ltd., Yongin-si (KR)

(72) Inventor: Tae Gon KIM, Yongin-si (KR)

(21) Appl. No.: 19/303,709

(22) Filed: Aug. 19, 2025

(30) Foreign Application Priority Data
Oct. 24, 2024 (KR) 10-2024-0146917

(51) Int. Cl. H10K 59/80

(52) U.S. Cl. CPC H10K 59/873; H10K 59/879

(57) ABSTRACT

A display device may include a display layer including a light emitting element including a first electrode, a second electrode, and a light emitting layer electrically connected to the first electrode and the second electrode, and a sensor layer on the display layer, the sensor layer including a conductive pattern layer, a protective layer at least partially on the conductive pattern layer, and an optical adhesive layer on the protective layer, the optical adhesive layer forming an interface with the protective layer and including an optical adhesive material. The protective layer may include a first protective layer covering the conductive pattern layer and a second protective layer spaced from the first protective layer and at least partially overlapping the light emitting layer in a plan view, and the second protective layer may include an edge portion which does not overlap the light emitting layer in a plan view.

### CROSS-REFERENCE TO RELATED APPLICATION

The present application claims priority to and the benefit of Korean Patent Application No. 10-2024-0146917, filed in the Korean Intellectual Property Office on Oct. 24, 2024, the entire content of which is incorporated herein by reference.

### BACKGROUND

### 1. Field

One or more aspects of embodiments of the present disclosure relate to a display device and an electronic device including the display device.

### 2. Description of the Related Art

In recent years, as interest in and demand for display devices capable of displaying information increase, research and development for a display device are continuously ongoing.

A display device may include a display panel for displaying an image and a sensing panel for sensing an object. The sensing panel may be used to determine a position of a touch input provided by a user.

Light provided by the display panel may be transmitted through the sensing panel and provided (e.g., transmitted) to the outside. The light emission direction of the light provided by the display panel is desired or required to be closely defined to improve the efficiency of the display device. Accordingly, research and development for improving the light output efficiency of the display device are continuously ongoing.

### SUMMARY

One or more aspects of embodiments of the present disclosure are directed toward a display device and an electronic device including the display device in which light output efficiency is enhanced (e.g., improved) and reliability of provided optical information may be enhanced (e.g., improved).

One or more aspects of embodiments of the present disclosure are directed toward a display device and an electronic device including the display device in which a viewing angle characteristic is improved.

Additional aspects will be set forth in part in the description which follows and, in part, will be apparent from the description, or may be learned by practice of the presented embodiments of the disclosure.

According to one or more embodiments of the disclosure, a display device may include a display layer including a light emitting element including a first electrode, a second electrode, and a light emitting layer electrically connected to the first electrode and the second electrode, and a sensor layer on the display layer, the sensor layer including a conductive pattern layer, a protective layer at least partially on the conductive pattern layer, and an optical adhesive layer on the protective layer, the optical adhesive layer forming an interface with the protective layer and including an optical adhesive material, the protective layer may include a first protective layer covering the conductive pattern layer and a second protective layer spaced and/or apart (e.g., spaced apart or separated) from the first protective layer and at least partially overlapping the light emitting layer in a plan view, and the second protective layer may include an edge portion which does not overlap the light emitting layer in a plan view.

According to one or more embodiments, the display device may include a sub-pixel area in which light of a color is provided and a non-sub-pixel area. The second protective layer may be located in the sub-pixel area, and at least a portion of the first protective layer may be arranged in the non-sub-pixel area. The sub-pixel area may include a first sub-pixel area, a second sub-pixel area, and a third sub-pixel area. The light emitting layer may include a first light emitting layer in the first sub-pixel area, a second light emitting layer in the second sub-pixel area, and a third light emitting layer in the third sub-pixel area. The second protective layer may include a (2-1)-th protective layer in the first sub-pixel area, a (2-2)-th protective layer in the second sub-pixel area, and a (2-3)-th protective layer in the third sub-pixel area. The edge portion may include a first edge portion in the first sub-pixel area, a second edge portion in the second sub-pixel area, and a third edge portion in the third sub-pixel area. The protective layer may have a refractive index greater than a refractive index of the optical adhesive layer.

According to one or more embodiments, the refractive index of the protective layer may be in a range of 1.50 to 1.58 (e.g., about 1.50 to about 1.58). The refractive index of the optical adhesive layer may be in a range of 1.46 to 1.50 (e.g., about 1.46 to about 1.50).

According to one or more embodiments, a side surface of the second protective layer may form a tapered surface in a forward direction. The (2-1)-th protective layer, the (2-2)-th protective layer, and the (2-3)-th protective layer may have shapes different from each other.

According to one or more embodiments, the first light emitting layer may include a first side extending in a first direction and a second side extending in a second direction different from the first direction. The first side of the first light emitting layer may be longer than the second side of the first light emitting layer. The first edge portion may be adjacent to the first side of the first light emitting layer in the second direction. The first light emitting layer may protrude in the first direction with respect to the (2-1)-th protective layer in a plan view.

According to one or more embodiments, the third light emitting layer may include a first side extending in the first direction and a second side extending in the second direction different from the first direction. The second side of the third light emitting layer may be longer than the first side of the third light emitting layer. The third edge portion may be adjacent to the second side of the third light emitting layer in the first direction. The third light emitting layer may protrude in the second direction with respect to the (2-3)-th protective layer in a plan view.

According to one or more embodiments, the second light emitting layer may include a first side extending in the first direction and a second side extending in the second direction different from the first direction. The first side of the second light emitting layer and the second side of the second light emitting layer may have a same length. A portion of the second edge portion may be adjacent to the first side of the second light emitting layer along the second direction, and another portion of the second edge portion may be adjacent to the second side of the second light emitting layer along the first direction. The second light emitting layer may be entirely covered by the (2-2)-th protective layer in a plan view.

According to one or more embodiments, each of the first light emitting layer, the second light emitting layer, and the third light emitting layer may include a first side extending in a first direction and a second side extending in a second direction different from the first direction. Each of the (2-1)-th protective layer and the (2-3)-th protective layer may include a plurality of portions. The (2-2)-th protective layer may be formed as a single piece.

According to one or more embodiments, the (2-1)-th protective layer may include a first portion and a second portion spaced and/or apart (e.g., spaced apart or separated) from each other with a separation area between the first portion and the second portion. The first portion and the second portion of the (2-1)-th protective layer may not be arranged on at least a portion of the first side of the first light emitting layer. The (2-3)-th protective layer may include a first portion and a second portion spaced and/or apart (e.g., spaced apart or separated) from each other with a separation area between the first portion and the second portion. The first portion and the second portion of the (2-3)-th protective layer may not be arranged on at least a portion of the second side of the third light emitting layer.

According to one or more embodiments, the separation area of the (2-1)-th protective layer may extend in the second direction, and the separation area of the (2-3)-th protective layer may extend in the first direction.

According to one or more embodiments, the separation area for the (2-1)-th protective layer may extend in a first diagonal direction between the first direction and the second direction. The separation area for the (2-3)-th protective layer may extend in a second diagonal direction between the first direction and the second direction.

According to one or more embodiments, the third sub-pixel area may be spaced and/or apart (e.g., spaced apart or separated) from the first sub-pixel area and the second sub-pixel area in a first direction. The first sub-pixel area and the second sub-pixel area may be spaced and/or apart (e.g., spaced apart or separated) from each other in a second direction different from the first direction.

According to one or more embodiments, the display device may include a sub-pixel area in which light of a color is provided and a non-sub-pixel area. The second protective layer may be located in the sub-pixel area, and at least a portion of the first protective layer may be located in the non-sub-pixel area. The sub-pixel area may include a first sub-pixel area to emit red light, a second sub-pixel area to emit green light, and a third sub-pixel area to emit blue light. The light emitting layer may include a first light emitting layer in the first sub-pixel area, a second light emitting layer in the second sub-pixel area, and a third light emitting layer in the third sub-pixel area. The second light emitting layer may include a first side and a second side having a same length. The second protective layer may be formed in the first sub-pixel area and the third sub-pixel area, and may not be formed in the second sub-pixel area.

According to one or more embodiments, the conductive pattern layer may include a first conductive pattern layer and a second conductive pattern layer located in different layers, and an insulating layer is located between the first conductive pattern layer and the second conductive pattern layer. The first protective layer may directly cover the second conductive pattern layer, and the second protective layer may not directly cover the second conductive pattern layer. The display layer may include an encapsulation layer covering the light emitting element. The sensor layer may include a sensor base layer where the conductive pattern layer is arranged. The sensor base layer may be directly on the encapsulation layer.

According to one or more embodiments of the disclosure, a display device may include a display layer including a light emitting element including a first electrode, a second electrode, and a light emitting layer electrically connected to the first electrode and the second electrode, and a sensor layer including a conductive pattern layer, a protective layer at least partially on the conductive pattern layer, an intermediate layer on the protective layer and forming an interface with the protective layer, and an optical adhesive layer on the intermediate layer and including an optical adhesive material. The protective layer may form an optical opening at least partially overlapping the light emitting layer in a plan view. At least a portion of the intermediate layer may be provided in the optical opening. At least a portion of the optical opening may not overlap the light emitting layer in a plan view.

According to one or more embodiments, the display device may include a sub-pixel area in which light of a color is provided and a non-sub-pixel area. At least a portion of the optical opening may be located in the sub-pixel area, and at least a portion of the protective layer may be located in the non-sub-pixel area. The sub-pixel area may include a first sub-pixel area, a second sub-pixel area, and a third sub-pixel area. The light emitting layer may include a first light emitting layer in the first sub-pixel area, a second light emitting layer in the second sub-pixel area, and a third light emitting layer in the third sub-pixel area. The optical opening may include a first optical opening in the first sub-pixel area, a second optical opening in the second sub-pixel area, and a third optical opening in the third sub-pixel area. The intermediate layer may have a refractive index greater than a refractive index of the protective layer.

According to one or more embodiments, the first optical opening, the second optical opening, and the third optical opening may have shapes different from each other.

According to one or more embodiments, each of the first light emitting layer, the second light emitting layer, and the third light emitting layer may include a first side extending in a first direction and a second side extending in a second direction different from the first direction. The first side of the first light emitting layer may be longer than the second side of the first light emitting layer. The first side of the second light emitting layer and the second side of the second light emitting layer may have a same length. The second side of the third light emitting layer may be longer than the first side of the third light emitting layer. At least a portion of the first optical opening which does not overlap the first light emitting layer may be adjacent to the first side of the first light emitting layer in the second direction in a plan view. The second light emitting layer may be entirely covered by the second optical opening in a plan view. At least a portion of the third optical opening which does not overlap the third light emitting layer may be adjacent to the second side of the third light emitting layer in the first direction in a plan view.

According to one or more embodiments, each of the first light emitting layer, the second light emitting layer, and the third light emitting layer may include a first side extending in a first direction and a second side extending in a second direction different from the first direction. The first optical opening may include a first optical portion and a second optical portion spaced and/or apart (e.g., spaced apart or separated) from each other with a separation area between the first optical portion and the second optical portion. The separation area for the first optical opening may extend in a diagonal direction between the first direction and the second direction, or in the second direction. The third optical opening may include a first optical portion, a second optical portion, and a third optical portion spaced and/or apart (e.g., spaced apart or separated) from each other with a separation area between the first optical portion, the second optical portion, and the third optical portion. The separation area for the third optical opening may extend in another diagonal direction between the first direction and the second direction, or in the first direction.

According to one or more embodiments of the disclosure, an electronic device includes a processor, a display device configured to display an image, and a power module configured to supply power to the display device. The display device includes a display layer including a light emitting element including a first electrode, a second electrode, and a light emitting layer electrically connected to the first electrode and the second electrode, and a sensor layer on the display layer, the sensor layer including a conductive pattern layer, a protective layer at least partially on the conductive pattern layer, and an optical adhesive layer on the protective layer, the optical adhesive layer forming an interface with the protective layer, and including an optical adhesive material. The protective layer may include a first protective layer covering the conductive pattern layer and a second protective layer spaced and/or apart (e.g., spaced apart or separated) from the first protective layer and at least partially overlapping the light emitting layer in a plan view. The second protective layer may include an edge portion which does not overlap the light emitting layer in a plan view.

According to one or more embodiments of the disclosure, a display device and an electronic device including the display device in which a viewing angle characteristic is improved may be provided.

According to one or more embodiments of the disclosure, a display device and an electronic device including the display device in which light output efficiency is improved and reliability of provided optical information may be improved may be provided.

For example, according to one or more embodiments of the disclosure, a display device and an electronic device including the display device may be provided, in which both the viewing angle characteristic and light output efficiency are enhanced, and the reliability of provided optical information is enhanced.

### BRIEF DESCRIPTION OF THE DRAWINGS

The above and other features of the disclosure will become more apparent by describing in further detail embodiments thereof with reference to the accompanying drawings, in which:

FIG. 1 is a drawing illustrating a display device according to one or more embodiments;

FIG. 2 is a schematic cross-sectional view illustrating a stack structure of a display device according to one or more embodiments;

FIG. 3 is a schematic cross-sectional view illustrating a display layer according to one or more embodiments;

FIG. 4 is a schematic cross-sectional view illustrating a sensor layer according to one or more embodiments;

FIG. 5 is a schematic plan view illustrating sensing electrodes according to one or more embodiments;

FIG. 6 is a schematic cross-sectional view illustrating a sensor layer and an upper layer according to one or more embodiments;

FIGS. 7 and 8 are schematic cross-sectional views each illustrating a display device according to one or more embodiments;

FIG. 9 is a schematic plan view illustrating sub-pixels and an area adjacent to the sub-pixels according to one or more embodiments;

FIGS. 10 and 11 are schematic cross-sectional views illustrating a display device according to one or more embodiments;

FIGS. 12-15 are schematic cross-sectional views illustrating sub-pixels and an area adjacent to the sub-pixels according to modified (e.g., alternative) embodiments, respectively;

FIG. 16 is a schematic cross-sectional view illustrating a sensor layer according to one or more embodiments;

FIG. 17 is a schematic cross-sectional view illustrating a sensor layer and an upper layer according to one or more embodiments;

FIGS. 18 and 19 are schematic cross-sectional views each illustrating a display device according to one or more embodiments;

FIG. 20 is a schematic cross-sectional view illustrating sub-pixels and an area adjacent to the sub-pixels according to one or more embodiments;

FIGS. 21 and 22 are schematic cross-sectional views illustrating a display device according to one or more embodiments;

FIGS. 23-26 are schematic plan views illustrating sub-pixels and an area adjacent to the sub-pixels according to modified (e.g., alternative) embodiments, respectively;

FIG. 27 is a block diagram of an electronic device according to an embodiment; and

FIG. 28 shows schematic views of various embodiments of an electronic device.

### DETAILED DESCRIPTION

The disclosure may be modified in one or more suitable manners and have one or more suitable forms. Therefore, specific embodiments will be illustrated in the drawings and will be described in more detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and/or the like may be used to describe one or more suitable components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, terms such as “include”, “have”, and/or the like are used to specify that there is a feature, a number, a (e.g., act or task) step, an operation, a component, a part, and/or a (e.g., any suitable) combination thereof described in the specification, but does not exclude a possibility of the presence or addition of one or more other features, numbers, steps, operations, components, parts, and/or one or more (e.g., any suitable) combinations thereof in advance. For example, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In addition, a case where a portion of a layer, a layer, an area, a plate, and/or the like is referred to as being “on” another portion, it includes not only a case where the portion is “directly on” another portion, but also a case where there is further another (e.g., intervening) portion between the portion and the other portion. In addition, in the present specification, in embodiments where a portion of a layer, a layer, an area, a plate, and/or the like is formed on another portion, a forming direction is not limited to an upper direction but includes forming the portion on a side surface and/or in a lower direction. Similarly, in embodiments where a portion of a layer, a layer, an area, a plate, and/or the like is formed “under” another portion, this includes not only a case where the portion is “directly under (beneath)” another portion but also a case where there is further another portion between the portion and the other portion. In contrast, when a portion of a layer, a layer, an area, a plate, and/or the like is referred to as being “directly on” or “directly under” another portion, no intervening elements are present.

As used herein, the singular forms “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The disclosure relates to a display device and an electronic device including the display device. Hereinafter, a display device and an electronic device including the display device according to one or more embodiments are described with reference to the accompanying drawings.

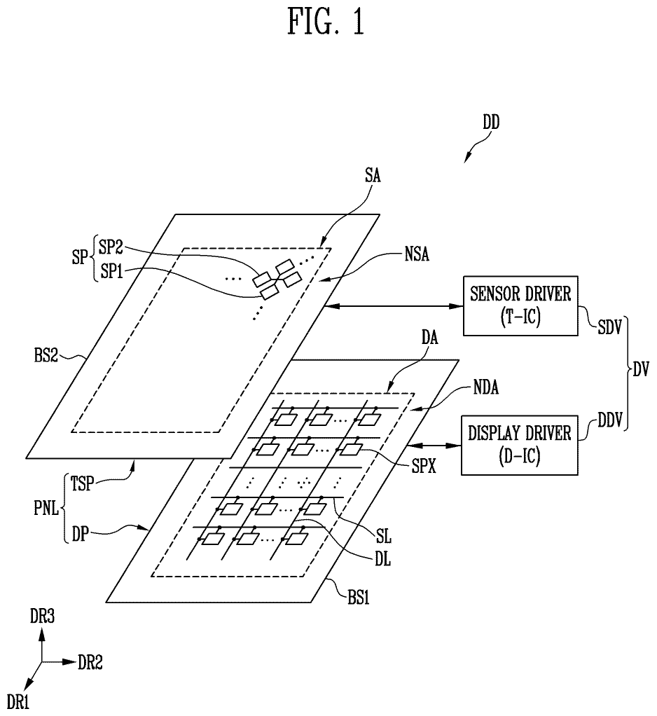

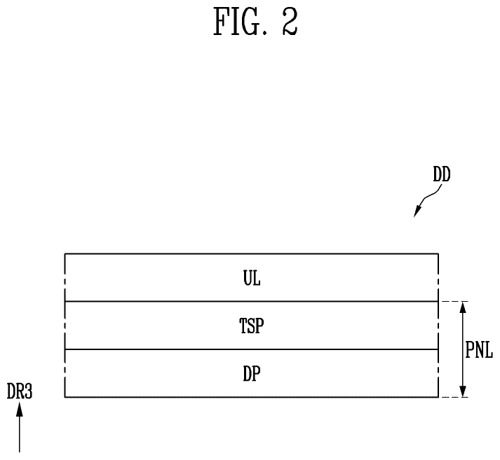

FIG. 1 is a diagram illustrating a display device according to one or more embodiments. FIG. 2 is a schematic cross-sectional view illustrating a stack structure of a display device according to one or more embodiments.

Referring to FIGS. 1 and 2, the display device DD is configured to provide (e.g., emit) light. According to one or more embodiments, the display device DD may be applied to one or more suitable devices, and an applicable device is not limited to a specific example.

The display device DD may include a panel PNL and a driving circuit unit DV for driving the panel PNL. The display device DD may further include an upper layer UL.

The panel PNL may include a display layer DP for displaying an image and a sensor layer TSP capable of sensing a user input (for example, a touch input).

The display layer DP may be referred to as a display panel. The sensor layer TSP may be referred to as a sensing panel.

The panel PNL may include sub-pixels SPX and sensing electrodes SP. According to one or more embodiments, the sub-pixels SPX may display an image in a unit of a display frame period. The sensing electrodes SP may sense an input (for example, a touch input) of a user in a unit of a sensing frame period. A sensing frame period and a display frame period may be independent of each other and/or may be different from each other. The sensing frame period and the display frame period may be synchronized or asynchronized with each other.

The sensor layer TSP including the sensing electrodes SP may obtain information on the touch input of the user (for example, in a mutual capacitance method). According to one or more embodiments, the sensing electrodes SP may include a first sensing electrode SP1 for providing a first sensing signal and a second sensing electrode SP2 for providing a second sensing signal. According to one or more embodiments, the first sensing electrode SP1 may be a Tx (transmitter) pattern electrode, and the second sensing electrode SP2 may be an Rx (receiver) pattern electrode. The information on the touch input (and/or a touch event) may refer to information including a position and/or the like of a touch that the user wants to provide.

However, the disclosure is not limited thereto. For example, according to one or more embodiments, the sensing electrodes SP may be configured of one type (kind) of sensing electrodes without distinction between the first sensing electrode SP1 and the second sensing electrode SP2 (for example, in a self-capacitance method).

The driving circuit unit DV may include a display driver (D-IC) DDV for driving the display layer DP and a sensor driver (T-IC) SDV for driving the sensor layer TSP.

The display layer DP may include a first base layer BS1 and the sub-pixels SPX provided on the first base layer BS1. The sub-pixels SPX may be located in a display area DA. The first base layer BS1 may be a display base layer.

The first base layer BS1 (and/or the display device DD) may include the display area DA in which an image is displayed and a non-display area NDA outside the display area DA. According to one or more embodiments, the display area DA may be located in a central area of the display layer DP, and the non-display area NDA may be located adjacent to a periphery of the display area DA.

The first base layer BS1 may be a base substrate (e.g., a base member) for supporting the display device DD. The first base layer BS1 may be a rigid substrate of a glass material. In some embodiments, the first base layer BS1 may include a silicon wafer. In some embodiments, the first base layer BS1 may be a flexible substrate of which bending, folding, rolling, and/or the like is possible. In this case, the first base layer BS1 may include an insulating material such as a polymer resin, for example, such as polyimide. However, the disclosure is not particularly limited thereto.

Gate lines SL (e.g., scan lines) and data lines DL, and the sub-pixels SPX electrically connected to the gate lines SL and the data lines DL may be located in the display area DA. The sub-pixels SPX may be configured to be selected by a scan signal of a turn-on level supplied from the gate lines SL, receive a data signal from the data lines DL, and emit light of a luminance corresponding to the data signal. Accordingly, an image corresponding to the data signal may be displayed in the display area DA. However, in the disclosure, a structure, a driving method, and/or the like of the sub-pixels SPX are not particularly limited.

One or more suitable lines and/or built-in circuit units connected to the sub-pixels SPX of the display area DA may be located in the non-display area NDA. For example, a plurality of lines for supplying one or more suitable power and control signals to the display area DA may be located in the non-display area NDA.

The display layer DP may output visual information (for example, an image). According to one or more embodiments, a type/kind of the display layer DP is not particularly limited. For example, the display layer DP may be implemented as a self-emission type (kind) display panel such as an organic light emitting display panel. However, each sub-pixel SPX is not necessarily limited to including only an organic light emitting element in case that the display layer DP is implemented as a self-emission type (kind). For example, a light emitting element of each sux-pixel SPX may include an organic light emitting diode, an inorganic light emitting diode, a quantum dot/well light emitting diode, and/or the like. According to one or more embodiments, the display layer DP may also be implemented as a non-emission type (kind) display panel such as a liquid crystal display panel. The display device DD may additionally include a light source such as a backlight unit in case that the display layer DP is implemented as a non-emission type (kind).

Hereinafter, for convenience of description, one or more embodiments in which the display layer DP is implemented as an organic light emitting display panel is described.

The sensor layer TSP includes a second base layer BS2 and sensing electrodes SP formed on the second base layer BS2. The sensing electrodes SP may be located in a sensing area SA on the second base layer BS2. The second base layer BS2 may be a sensor base layer.

The second base layer BS2 (and/or the display device DD) may include the sensing area SA where a touch input and/or the like may be sensed, and a non-sensing area NSA around the sensing area SA. According to one or more embodiments, the sensing area SA may be located to overlap at least one area of the display area DA. For example, the sensing area SA may be set as an area corresponding to the display area DA (for example, an area overlapping the display area DA), and the non-sensing area NSA may be set as an area corresponding to the non-display area NDA (for example, an area overlapping the non-display area NDA). In this case, the touch input may be detected through the sensor layer TSP in case that the touch input and/or the like is provided on the display area DA.

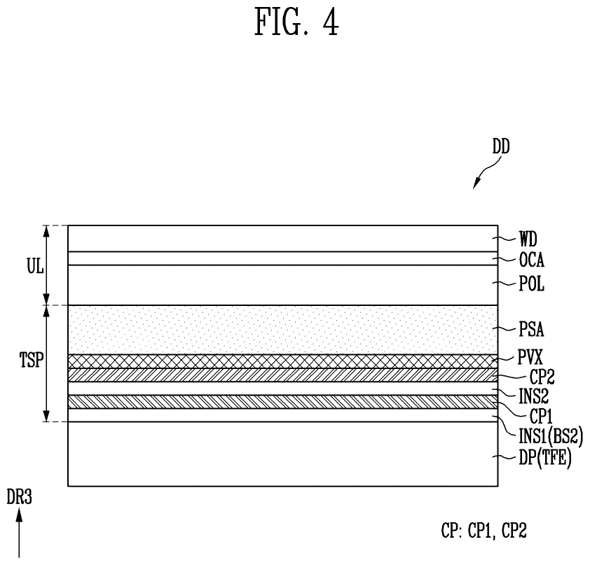

The second base layer BS2 may include one or more insulating layers (for example, a first insulating layer INS1 (refer to FIG. 4)). For example, the first insulating layer INS1 for forming the second base layer BS2 may be on the display layer DP to form a base for forming the sensing electrodes SP. However, an example for forming the second base layer BS2 is not particularly limited.

The sensing area SA may be set as an area capable of responding to the touch input (e.g., an active area of a sensor). To this end, the sensing electrodes SP for sensing the touch input and/or the like may be located in the sensing area SA.

The sensor layer TSP may obtain information on an input provided from the user. The sensor layer TSP may recognize the touch input. The sensor layer TSP may recognize the touch input using a capacitive sensing method. The sensor layer TSP may sense the touch input using a mutual capacitance method or may sense the touch input using a self-capacitance method.

According to one or more embodiments, each of the first sensing electrodes SP1 may extend in a first direction DR1. The first sensing electrodes SP1 may be arranged in a second direction DR2. The second direction DR2 may be different from the first direction DR1. For example, the second direction DR2 may be a direction normal (e.g., perpendicular or substantially perpendicular) to the first direction DR1.

According to one or more embodiments, each of the second sensing electrodes SP2 may extend in the second direction DR2. The second sensing electrodes SP2 may be arranged in the first direction DR1.

According to one or more embodiments, the first sensing electrodes SP1 and the second sensing electrodes SP2 may have the same (for example, substantially the same) shape. For example, the first sensing electrodes SP1 which are Tx pattern electrodes and the second sensing electrodes SP2 which are Rx pattern electrodes may have a corresponding shape (for example, substantially the same shape), and thus sensing performance of the touch event may be uniformly (e.g., substantially uniformly) set within the sensing area SA.

Sensing lines for electrically connecting the sensing electrodes SP to a sensor driver SDV and/or the like may be located in the non-sensing area NSA of the sensor layer TSP.

The driving circuit unit DV may include the display driver DDV for driving the display layer DP and the sensor driver SDV for driving the sensor layer TSP.

The display driver DDV is configured to be electrically connected to the display layer DP to drive the sub-pixels SPX. The sensor driver SDV is configured to be electrically connected to the sensor layer TSP to drive the sensor layer TSP.

The upper layer UL may be on a substantially outer side of the display device DD. The upper layer UL may be on the sensor layer TSP. Light provided from the display layer DP may pass through the upper layer UL and may be output to an outside. According to one or more embodiments, the upper layer UL may include a window unit WD (refer to FIG. 4). According to one or more embodiments, the upper layer UL may further include a polarizing layer POL (refer to FIG. 4). However, the disclosure is not limited thereto. The upper layer UL may further include a color filter layer that selectively transmits light of a set or predetermined color.

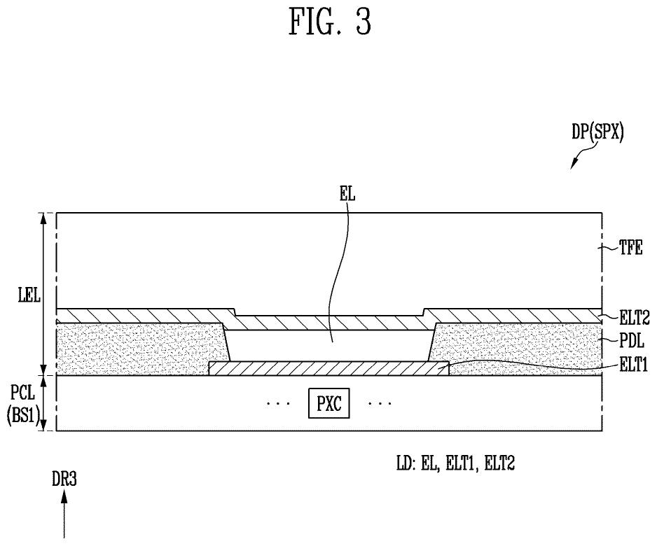

With reference to FIG. 3, one or more embodiments of the display layer DP will be described. FIG. 3 is a schematic cross-sectional view illustrating a display layer according to one or more embodiments. For convenience of description, FIG. 3 schematically shows a sub-pixel SPX included in the display layer DP according to one or more embodiments.

Referring to FIG. 3, the display layer DP (and/or the sub-pixel SPX) may include a pixel circuit layer PCL and a light emitting element layer LEL.

The pixel circuit layer PCL may include a pixel circuit PXC for driving light emitting elements LD. The pixel circuit layer PCL may include the first base layer BS1, conductive layers for forming the pixel circuits PXC, and insulating layers located between the conductive layers.

The pixel circuit PXC may include circuit elements including a transistor. The pixel circuit PXC may include a driving transistor. The pixel circuit PXC may be electrically connected to the light emitting elements LD and may provide an electrical signal for the light emitting elements LD to emit light.

The light emitting element layer LEL may be on the pixel circuit layer PCL. According to one or more embodiments, the light emitting element layer LEL may include a light emitting element LD, a pixel defining layer PDL, and an encapsulation layer TFE.

The light emitting element LD may be on the pixel circuit layer PCL. According to one or more embodiments, the light emitting element LD may include a first electrode ELT1, a light emitting layer EL, and a second electrode ELT2. According to one or more embodiments, the light emitting layer EL may be located in an area defined by the pixel defining layer PDL. The pixel defining layer PDL may be adjacent to a periphery of the light emitting layer EL. One surface of the light emitting layer EL may be electrically connected to the first electrode ELT1, and another surface of the light emitting layer EL may be electrically connected to the second electrode ELT2.

The first electrode ELT1 may be an anode electrode for the light emitting layer EL, and the second electrode ELT2 may be a common electrode (and/or a cathode electrode) for the light emitting layer EL. According to one or more embodiments, the first electrode ELT1 and the second electrode ELT2 may include a conductive material. For example, the first electrode ELT1 may include a conductive material including a reflective property, and the second electrode ELT2 may include a transparent conductive material. However, the disclosure is not limited thereto.

The light emitting layer EL may have a multilayer thin film structure including a light generation layer. The light emitting layer EL may include a hole injection layer for injecting a hole, a hole transport layer which has an excellent or suitable hole transport property and may increase or improve a recombination opportunity of a hole and an electron by suppressing or reducing movement of an electron which is not combined in the light generation layer, the light generation layer for emitting light by recombination of injected electron and hole, a hole blocking layer for suppressing or reducing movement of a hole which is not combined in the light generation layer, an electron transport layer for smoothly or suitably transporting an electron to the light generation layer, and an electron injection layer for injecting an electron. The light emitting layer EL may be to emit light based on an electrical signal provided from the first electrode ELT1 and the second electrode ELT2.

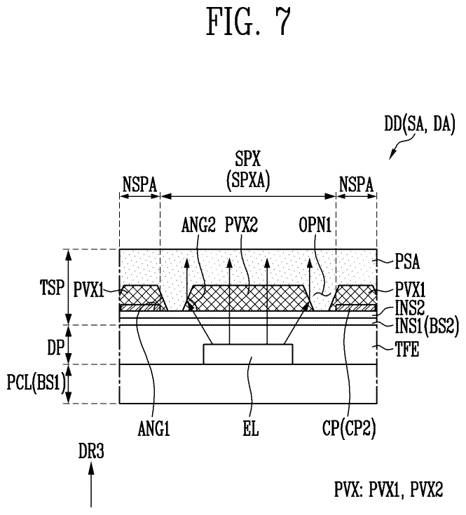

The light emitting layer EL may provide light of a set or predetermined color. The light emitting layer EL may form the sub-pixel SPX. The light emitting layer EL may form a sub-pixel area SPXA (refer to FIG. 7) from which light of a set color is to be emitted. An area of the light emitting layer EL and the sub-pixel area SPXA may correspond to each other in a plan view (e.g., when viewed from the top such as along a third direction DR3). For example, the respective light emitting layers EL may correspond to the respective sub-pixel areas SPXA.

The pixel defining layer PDL may be on the pixel circuit layer PCL to define a position where the light emitting layer EL is arranged. According to one or more embodiments, the pixel defining layer PDL may include an inorganic material. However, the disclosure is not limited thereto. The pixel defining layer PDL may also include an organic material.

The encapsulation layer TFE may be on the light emitting element LD. The encapsulation layer TFE may cover the light emitting element LD. The encapsulation layer TFE may offset (e.g., planarize) a step generated by the light emitting element LD and the pixel defining layer PDL. The encapsulation layer TFE may include a plurality of insulating layers covering the light emitting element LD. According to one or more embodiments, the encapsulation layer TFE may have a structure in which an inorganic layer and an organic layer are alternately stacked. According to one or more embodiments, the encapsulation layer TFE may be a thin film encapsulation layer.

With reference to FIGS. 4-15, a display device DD according to one or more embodiments is described. For convenience of description, a content that may overlap the content described above is briefly described or is not repeated.

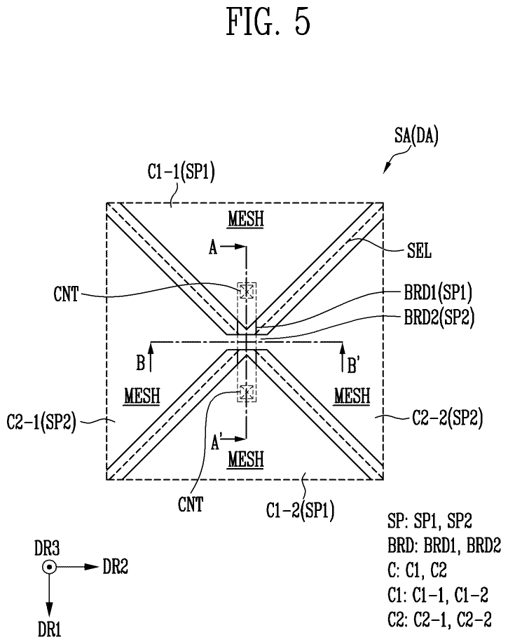

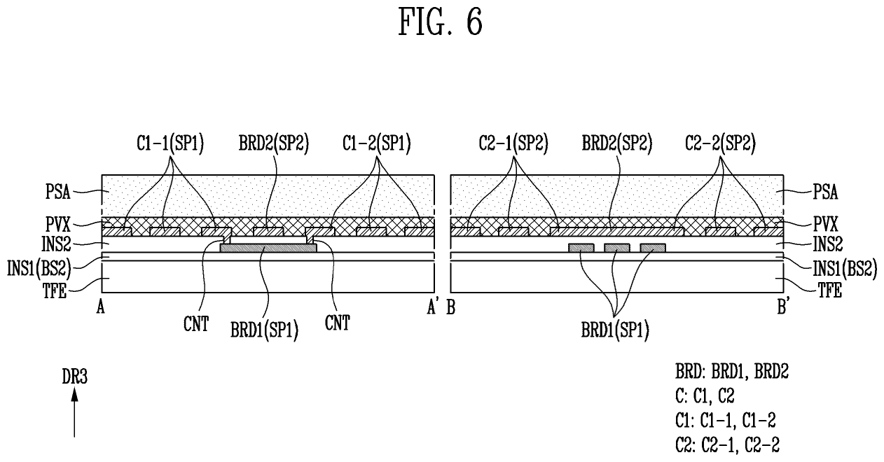

FIG. 4 is a schematic cross-sectional view illustrating a sensor layer according to one or more embodiments. FIG. 5 is a schematic plan view illustrating sensing electrodes according to one or more embodiments. FIG. 5 shows a schematic plan structure illustrating an area where the first sensing electrode SP1 and the second sensing electrode SP2 are adjacent to each other. FIG. 6 is a schematic cross-sectional view illustrating a sensor layer and an upper layer according to one or more embodiments. FIG. 6 shows a schematic cross-sectional structure according to A˜A′ (e.g., cut along the A˜A′ line) of FIG. 5 and a cross-sectional structure according to B˜B′ (e.g., cut along the B˜B′ line) of FIG. 6.

Referring to FIGS. 4-6, the sensor layer TSP may be on the display layer DP (for example, the encapsulation layer TFE). The sensor layer TSP may include a first insulating layer INS1, a conductive pattern layer CP, a second insulating layer INS2, a protective layer PVX, and an optical adhesive layer PSA.

According to one or more embodiments, the conductive pattern layer CP may include one or more layers. For example, the conductive pattern layer CP may include a first conductive pattern layer CP1 and a second conductive pattern layer CP2. The conductive pattern layer CP may be patterned in an area to form sensing electrodes SP.

For example, the first conductive pattern layer CP1 and the second conductive pattern layer CP2 may be patterned in an area to form the sensing electrodes SP. For example, a portion of the first conductive pattern layer CP1 may configure the first sensing electrode SP1, and a portion of each of the first conductive pattern layer CP1 and the second conductive pattern layer CP2 may form the second sensing electrode SP2. In one or more embodiments, a portion of the second conductive pattern layer CP2 may configure the first sensing electrode SP1, and a portion of each of the first conductive pattern layer CP1 and the second conductive pattern layer CP2 may form the second sensing electrode SP2. However, the disclosure is not limited thereto.

The first insulating layer INS1 may be located (for example, directly located) on the encapsulating layer TFE. The first insulating layer INS1 may form the second base layer BS2 to provide an area where the first conductive pattern layer CP1, the second insulating layer INS2, the second conductive pattern layer CP2, and the protective layer PVX are located. The first insulating layer INS1 may form the second base layer BS2 and may be referred to as a sensor base layer.

The first conductive pattern layer CP1 may be on the first insulating layer INS1. The second conductive pattern layer CP2 may be on the second insulating layer INS2. The first conductive pattern layer CP1 and the second conductive pattern layer CP2 may be spaced and/or apart (e.g., spaced apart or separated) from each other with the second insulating layer INS2 interposed between the first conductive pattern layer CP1 and the second conductive pattern layer CP2.

The first conductive pattern layer CP1 and the second conductive pattern layer CP2 may include a metal layer of (e.g., including) a single layer or multiple layers. The first conductive pattern layer CP1 and the second conductive pattern layer CP2 may include at least one of suitable metal materials including gold (Au), silver (Ag), aluminum (Al), molybdenum (Mo), chromium (Cr), titanium (Ti), nickel (Ni), neodymium (Nd), copper (Cu), platinum (Pt), and/or the like, and/or an alloy thereof. According to one or more embodiments, the first conductive pattern layer CP1 and the second conductive pattern layer CP2 may include at least one of suitable transparent conductive materials including silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO₂), carbon nanotube, and/or graphene.

The second insulating layer INS2 may be on the first conductive pattern layer CP1. The second insulating layer INS2 may be interposed between the first conductive pattern layer CP1 and the second conductive pattern layer CP2. The protective layer PVX may be on the second conductive pattern layer CP2.

The first insulating layer INS1 may include at least one selected from among an inorganic material and an organic material. The second insulating layer INS2 may include at least one selected from among an inorganic material and an organic material. According to one or more embodiments, the inorganic material may include at least one selected from among an inorganic material and an organic material. The inorganic material may include at least one selected from among silicon nitride (SiNx), silicon oxide (SiOx), silicon oxynitride (SiOxNy), and aluminum oxide (AlOx). The organic material may include at least one selected from among an acrylic resin, an epoxy resin, a phenol resin, a polyamide resin, and a polyimide resin. However, the disclosure is not limited thereto.

The sensing electrodes SP may include a cell C and a bridge BRD. The cell C may have a relatively large area, and the bridge BRD may have a relatively small area. The cells C adjacent to each other may be electrically connected by the bridge BRD. The cell C may include a first cell C1 and a second cell C2. The bridge BRD may include a first bridge BRD1 and a second bridge BRD2.

According to one or more embodiments, the first cell C1 and the second cell C2 may be formed by the second conductive pattern layer CP2. The second bridge BRD2 may be formed by the second conductive pattern layer CP2. A portion of the first bridge BRD1 may be formed by the first conductive pattern layer CP1, and another portion of the first bridge BRD1 may be formed by the second conductive pattern layer CP2.

However, the disclosure is not necessarily limited thereto. For example, the first cell C1 and the second cell C2 may be formed by the first conductive pattern layer CP1. The second bridge BRD2 may be formed by the first conductive pattern layer CP1. A portion of the first bridge BRD1 may be formed by the second conductive pattern layer CP2, and another portion of the first bridge BRD1 may be formed by the first conductive pattern layer CP1.

According to one or more embodiments, the sensing electrodes SP may have a mesh structure. The cells C and the bridges BRD may have a mesh structure. For example, the second conductive pattern layer CP2 for forming the sensing electrodes SP may be patterned according to (e.g., in the form of) a mesh structure. Because the sensing electrodes SP have the mesh structure, a capacitance which may be formed with other electrodes located under the cells C may be reduced.

The first sensing electrode SP1 may have a structure in which the first cells C1 of a relatively large area and the first bridge BRD1 of a relatively narrow area are connected. For example, the first cell C1 may include a (1-1)-th cell C1-1 and a (1-2)-th cell C1-2, and the first bridge BRD1 may electrically connect the (1-1)-th cell C1-1 and the (1-2)-th cell C1-2.

The second sensing electrode SP2 may have a structure in which the second cells C2 of a relatively large area and the second bridge BRD2 of a relatively narrow area are connected. For example, the second cell C2 may include a (2-1)-th cell C2-1 and a (2-2)-th cell C2-2 and the second bridge BRD2 may electrically connect the (2-1)-th cell C2-1 and the (2-2)-th cell C2-2.

According to one or more embodiments, the first bridge BRD1 may be electrically connected to the (1-1)-th cell C1-1 through a contact portion CNT and may be electrically connected to the (1-2)-th cell C1-2 through another contact portion CNT. Accordingly, the first bridge BRD1 located in a layer different from a layer of the first cell C1 may electrically connect the (1-1)-th cell C1-1 and the (1-2)-th cell C1-2 through the contact portion CNT. According to one or more embodiments, the contact portion CNT may pass through the second insulating layer INS2.

The first cell C1 and the second cell C2 may have a diamond shape overall. For example, The first cell C1 and the second cell C2 may have an overall or substantial diamond shape. However, a shape of the first cell C1 and the second cell C2 is not particularly limited thereto. For example, the first cell C1 and the second cell C2 may have a quadrangle shape overall (e.g., the first cell C1 and the second cell C2 may have an overall or substantial quadrangle shape).

The first sensing electrodes SP1 and the second sensing electrodes SP2 may be adjacent to each other with a separation line SEL interposed between the first sensing electrodes SP1 and the second sensing electrodes SP2. The separation line SEL may be a virtual line located in an area between the first sensing electrodes SP1 and the second sensing electrodes SP2. For example, the separation line SEL may be located between the (1-1)-th cell C1-1 and the (1-2)-th cell C1-2. The separation line SEL may be located between the first bridge BRD1 and the (1-2)-th cell C1-2.

The protective layer PVX may be on the conductive pattern layer CP. For example, the protective layer PVX may be directly on the conductive pattern layer CP. The protective layer PVX may be located (for example, directly located) on the second conductive pattern layer CP2. The protective layer PVX may be interposed between the conductive pattern layer CP and the optical adhesive layer PSA.

The optical adhesive layer PSA may be on the protective layer PVX. For example, the optical adhesive layer PSA may be directly on the protective layer PVX. The optical adhesive layer PSA may be located across the sub-pixel areas SPXA in a plan view.

According to one or more embodiments, the optical adhesive layer PSA may include an optical adhesive material.

The optical adhesive layer PSA may bond other configurations of the sensor layer TSP and the upper layer UL. For example, each of layers of the display device DD may be sequentially on the first base layer BS1, and the optical adhesive layer PSA may combine adjacent different layers. The optical adhesive layer PSA may be directly adjacent to a lowermost portion of the upper layer UL.

According to one or more embodiments, the optical adhesive layer PSA may have a thicker thickness compared to the protective layer PVX.

The optical adhesive layer PSA may be to transmit applied light. The optical adhesive layer PSA may define a light path.

The optical adhesive layer PSA may form an interface with the protective layer PVX. According to one or more embodiments, light provided from the display layer DP (for example, the light emitting element LD) may be refracted at the interface between the optical adhesive layer PSA and the protective layer PVX, and the display device DD may provide the light to an outside along a set or intended path. A content related to this is described in more detail later with reference to drawings after FIG. 7.

The upper layer UL may be on the sensor layer TSP (for example, the optical adhesive layer PSA). For example, the upper layer UL may be directly on the optical adhesive layer PSA.

In one or more embodiments, the upper layer UL may include a polarizing layer POL, a transparent adhesive layer OCA, and a window unit WD.

The polarizing layer POL may be on the optical adhesive layer PSA. The polarizing layer POL may be in contact with the optical adhesive layer PSA.

The polarizing layer POL may be configured to polarize applied light. According to one or more embodiments, the polarizing layer POL may include a λ/4 phase difference film. According to one or more embodiments, the polarizing layer POL may include an absorptive polarizing layer, and may also include a reflective polarizing layer (for example, a wire grid polarizing layer). However, the disclosure is not limited thereto.

The transparent adhesive layer OCA may include an optically clear adhesive (OCA) material suitable in the art, and is not limited to a specific example.

The transparent adhesive layer OCA may be located between the polarizing layer POL and the window unit WD. The transparent adhesive layer OCA may combine (e.g., bond together) the polarizing layer POL and the window unit WD.

The window unit WD may be on the outside of the display device DD and may be to transmit light. The window unit WD may protect other layers of the display device DD.

With reference to FIGS. 7-15, a display device DD is described in more detail in conjunction with a light path and/or the like defined in the display device DD according to one or more embodiments. A content that may overlap the content described above is briefly described or is not repeated.

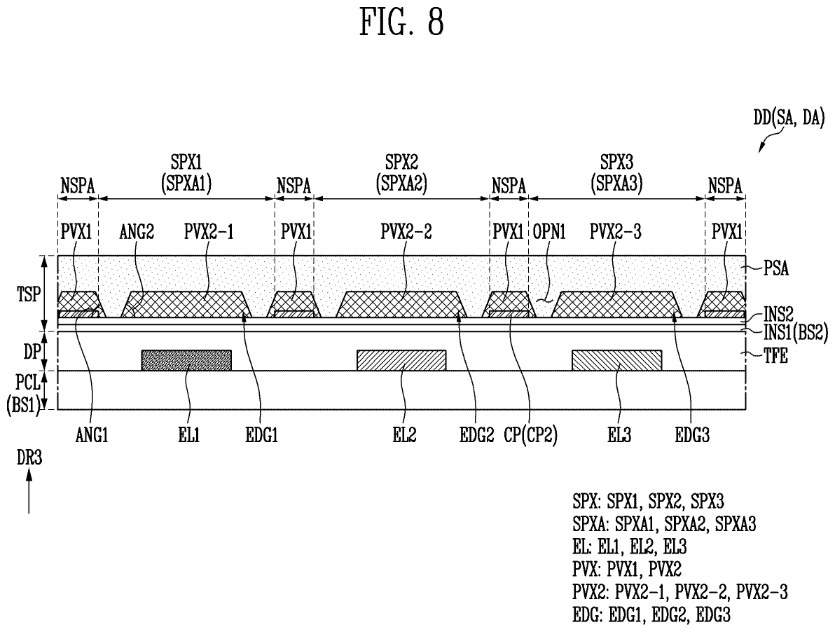

FIGS. 7 and 8 are each a schematic cross-sectional view illustrating a display device according to one or more embodiments. FIG. 7 schematically shows a partial cross-sectional structure of a display device DD forming a sub-pixel SPX according to one or more embodiments. FIG. 7 schematically shows a light path of light provided by the light emitting layer EL. For example, a light path of the light provided by the light emitting layer EL is expressed by an arrow. FIG. 8 schematically shows a partial cross-sectional structure of a display device DD forming first to third sub-pixels SPX1 to SPX3 according to one or more embodiments.

FIGS. 7 and 8 show a structure in which a portion of a conductive pattern layer CP (for example, a portion of the second conductive pattern layer CP2) forms the cell C according to one or more embodiments, and shows an area in which another portion of the conductive pattern layer CP (for example, a portion of the first conductive pattern layer CP1) is not located for convenience of description. For convenience of description, FIGS. 7 and 8 briefly show the display layer DP. For example, FIGS. 7 and 8 show the light emitting layer EL and the encapsulating layer TFE on the pixel circuit layer PCL, and some configurations such as the first and second electrodes ELT1 and ELT2 are omitted (e.g., are not shown). For convenience of description, FIGS. 7 and 8 do not show the upper layer UL. Applied light may pass through the upper layer UL and may be emitted to an outside.

Referring to FIGS. 7 and 8, the light provided by the light emitting layer EL may pass through the optical adhesive layer PSA and may be provided to the outside of the display device DD along the light path.

In a plan view, the light emitting layer EL may be located in the sub-pixel area SPXA. In a plan view, the light emitting layer EL may be located to correspond to an area where the sub-pixel SPX is recognized.

The light emitting layer EL may be to emit light of a color. For example, the sub-pixel SPX may include the first sub-pixel SPX1 that provides light of a first color (for example, red), the second sub-pixel SPX2 that provides light of a second color (for example, green), and the third sub-pixel SPX3 that provides light of a third color (for example, blue).

The sub-pixel area SPXA may include a first sub-pixel area SPXA1 formed by the first sub-pixel SPX1 and in which light of the first color is recognized, a second sub-pixel area SPXA2 formed by the second sub-pixel SPX2 and in which light of the second color is recognized, and a third sub-pixel area SPXA3 formed by the third sub-pixel SPX3 and in which light of the third color is recognized.

According to one or more embodiments, the display device DD may include a non-sub-pixel area NSPA. The non-sub-pixel area NSPA may be an area in which light of a color is not recognized (e.g., is not seen by a viewer). The non-sub-pixel area NSPA may be formed between adjacent sub-pixel areas SPXA.

According to one or more embodiments, the light emitting layer EL may provide light of different colors in each of the first to third sub-pixels SPX1 to SPX3. For example, the light emitting layer EL may include a first light emitting layer included in the first sub-pixel SPX1 and providing the light of the first color, a second light emitting layer included in the second sub-pixel SPX2 and providing the light of the second color, and a third light emitting layer included in the third sub-pixel SPX3 and providing the light of the third color. However, the disclosure is not limited thereto. For example, the light emitting layers EL may be to emit light of a same color in each of the first to third sub-pixels SPX1 to SPX3, the display device DD may further include a quantum-dot layer and/or a color filter layer, and thus a full-color of display device structure may be implemented.

The protective layer PVX may be located in a partial area on the second insulating layer INS2. The protective layer PVX may entirely cover the conductive pattern layer CP. For example, the protective layer PVX may entirely cover the second conductive pattern layer CP2.

The protective layer PVX may be around (e.g., surround) an area in a plan view and may form an adjacent opening OPN1.

The protective layer PVX may include a first protective layer PVX1 and a second protective layer PVX2. The first protective layer PVX1 and the second protective layer PVX2 may be adjacent to each other with the adjacent opening OPN1 interposed between the first protective layer PVX1 and the second protective layer PVX2.

The first protective layer PVX1 and the second protective layer PVX2 may be formed in a same process and may include a same material.

At least a portion of the first protective layer PVX1 may be located in the non-sub-pixel area NSPA. The first protective layer PVX1 may not overlap the light emitting layer EL in a plan view. The first protective layer PVX1 may cover (for example, directly cover) the conductive pattern layer CP (for example, the second conductive pattern layer CP2).

A position of the second protective layer PVX2 may correspond to the sub-pixel SPX (for example, the sub-pixel area SPXA). The second protective layer PVX2 may be located in the sub-pixel area SPXA. The second protective layer PVX2 may overlap the light emitting layer EL in a plan view. The second protective layer PVX2 may not cover (e.g., does not come into contact with or line or top of) the conductive pattern layer CP (for example, the second conductive pattern layer CP2).

The second protective layer PVX2 may include a (2-1)-th protective layer PVX2-1 located in the first sub-pixel area SPXA1 and overlapping the first light emitting layer EL1, a (2-2)-th protective layer PVX2-2 located in the second sub-pixel area SPXA2 and overlapping the second light emitting layer EL2, and a (2-3)-th protective layer PVX2-3 located in the third sub-pixel area SPXA3 and overlapping the third light emitting layer EL3.

The protective layer PVX may be in contact with the optical adhesive layer PSA. According to one or more embodiments, an interface formed by the protective layer PVX and the optical adhesive layer PSA may extend in a diagonal direction (for example, a direction different from the third direction DR3).

For example, a side surface of the first protective layer PVX1 may form a first angle ANG1 with respect to a plane where the first base layer BS1 is arranged. A side surface of the second protective layer PVX2 may form a second angle ANG2 with respect to the plane where the first base layer BS1 is arranged. The first angle ANG1 and the second angle ANG2 may be acute angles. Accordingly, the side surface of the second protective layer PVX2 located in the sub-pixel area SPXA and overlapping the light emitting layer EL may form a tapered surface in a forward (e.g., upward) direction.

The protective layer PVX may include an edge portion EDG. According to one or more embodiments, the edge portion EDG of the protective layer PVX may face the adjacent opening OPN1. The edge portion EDG of the protective layer PVX may face the side surface of the first protective layer PVX1. The edge portion EDG may be a portion of the protective layer PVX and may not overlap the light emitting layer EL in a plan view.

For example, the edge portion EDG may include a first edge portion EDG1 located in the first sub-pixel area SPXA1 and formed in the (2-1)-th protective layer PVX2-1, a second edge portion EDG2 located in the second sub-pixel area SPXA2 and formed in the (2-2)-th protective layer PVX2-2, and a third edge portion EDG3 located in the third sub-pixel area SPXA3 and formed in the (2-3)-th protective layer PVX2-3.

According to one or more embodiments, the first edge portion EDG1 may not overlap the first light emitting layer EL1 in a plan view. The second edge portion EDG2 may not overlap the second light emitting layer EL2 in a plan view. The third edge portion EDG3 may not overlap the third light emitting layer EL3 in a plan view.

The protective layer PVX may include an organic material. For example, the protective layer PVX may include one or more selected from among an acrylic resin, an epoxy resin, a phenol resin, a polyamide resin, a polyimide resin, a methacrylic resin, a polyisoprene resin, a vinyl resin, a urethane resin, a cellulose resin, a siloxane resin, and a perylene resin. However, the disclosure is not limited thereto.

The protective layer PVX may have a refractive index (for example, a first refractive index) greater than a refractive index of the optical adhesive layer PSA. For example, the refractive index of the protective layer PVX may be in a range of 1.50 to 1.58. According to one or more embodiments, the protective layer PVX may have a refractive index of about 1.54. However, the disclosure is not limited thereto.

The optical adhesive layer PSA may entirely cover the protective layer PVX, and at least a portion of the optical adhesive layer PSA may be adjacent (for example, directly adjacent) to the second protective layer PVX2. The optical adhesive layer PSA may be a light transmitting adhesive layer, and may be an optical layer that forms an interface with the second protective layer PVX2 to change the light path.

The interface between the second protective layer PVX2 and the optical adhesive layer PSA may be formed at the edge portion EDG. A formation range of the interface (e.g., the position, length and/or angle of the interface) between the second protective layer PVX2 and the optical adhesive layer PSA may be determined according to a position of the edge portion EDG.

The optical adhesive layer PSA may have the refractive index (for example, a second refractive index) less than the refractive index of the protective layer PVX. For example, the refractive index of the optical adhesive layer PSA may be in a range of 1.46 to 1.50. According to one or more embodiments, the optical adhesive layer PSA may have a refractive index of about 1.48. However, the disclosure is not limited thereto.

According to one or more embodiments, at least a portion of the light provided by the light emitting layer EL may be transmitted through the second protective layer PVX2 and the optical adhesive layer PSA. For example, the light emitting layer EL may overlap the second protective layer PVX2 in a plan view, and the light emitted by the light emitting layer EL may be transmitted through the optical adhesive layer PSA through the second protective layer PVX2 and may be recognized (e.g., may be seen) from a front surface of the display device DD.

According to one or more embodiments, a portion of the light provided by the light emitting layer EL may be refracted at the interface between the second protective layer PVX2 and the optical adhesive layer PSA and may be transmitted through the optical adhesive layer PSA. For example, as at least a portion of the light emitted by the light emitting layer EL, a portion of the emitted light generally opposite to (e.g., facing) the diagonal direction (for example, the direction different from the third direction DR3) may be provided at the interface between the second protective layer PVX2 and the optical adhesive layer PSA. At this time, due to a refractive index difference between the second protective layer PVX2 and the optical adhesive layer PSA, the provided light may be refracted so as to generally face the front surface, and may be guided to a display direction (for example, the third direction DR3) of the display device DD. Accordingly, light emission efficiency of the light emitting element LD may be improved, and power desired or required to implement an image of the same (e.g., set or predetermined suitable) luminance may be reduced. For example, according to one or more embodiments, the display device DD with improved light output efficiency may be provided.

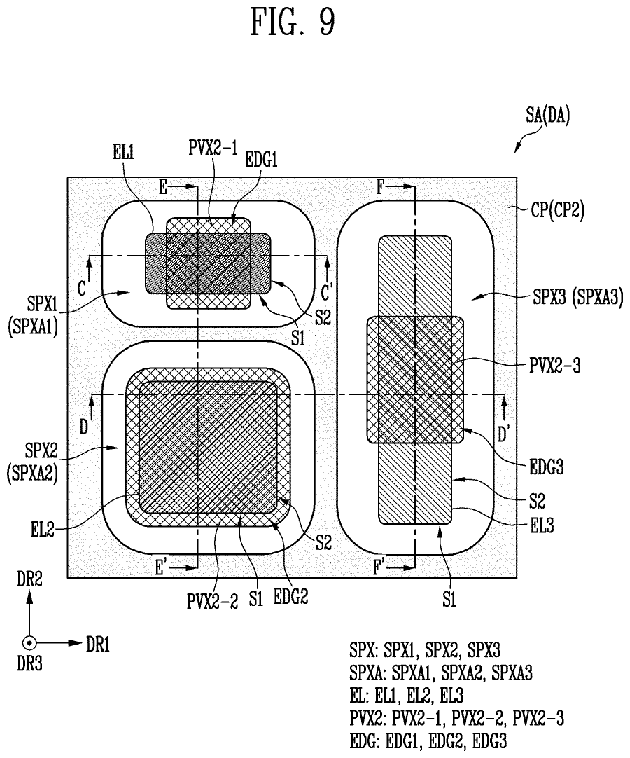

According to one or more embodiments, a location range of the second protective layer PVX2 may be adjusted, and thus a viewing angle characteristic for each of the sub-pixel SPX may be improved. This is described in more detail herein below with reference to FIGS. 9-15.

FIGS. 9-15 show the display area DA and the sensing area SA overlapping each other as a partial area of the display device DD.

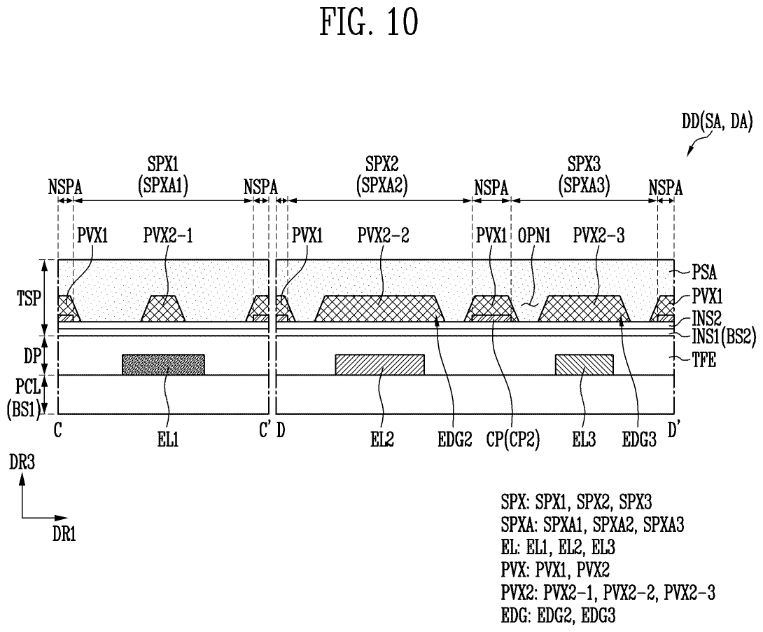

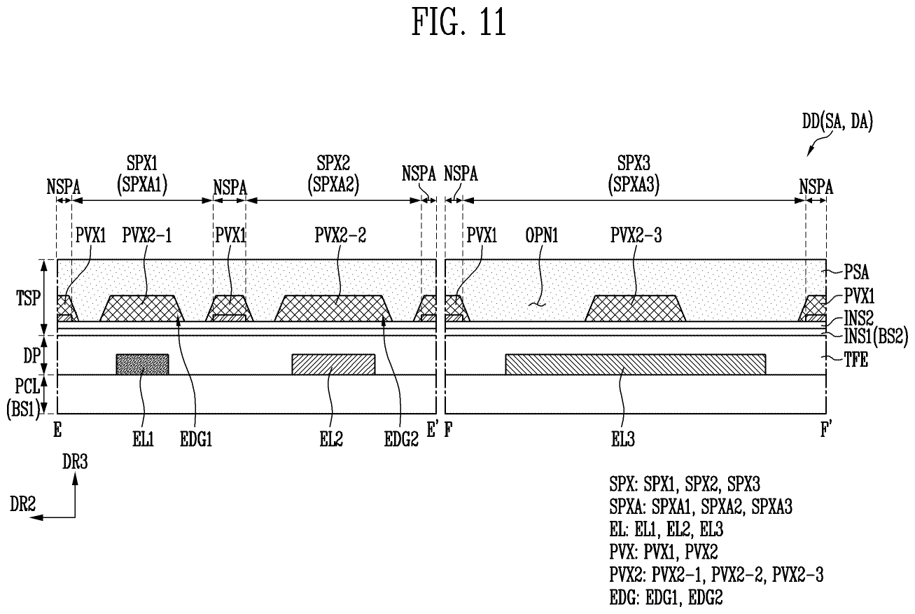

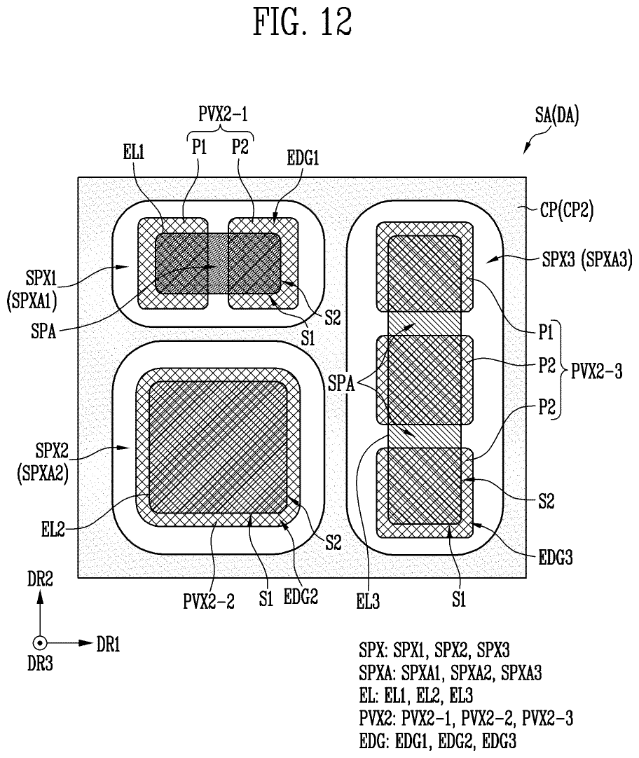

FIG. 9 is a schematic plan view illustrating sub-pixels and an area adjacent to the sub-pixels according to one or more embodiments. FIGS. 10 and 11 are schematic cross-sectional views illustrating a display device according to one or more embodiments. FIG. 10 is a schematic cross-sectional view taken along the line C˜C′ of FIG. 9 and a schematic cross-sectional view taken along the line D˜D′ of FIG. 9. FIG. 11 is a schematic cross-sectional view taken along the line E˜E′ of FIG. 9 and a schematic cross-sectional view taken along the line F˜F′ of FIG. 9. FIGS. 12-15 are schematic plan views illustrating sub-pixels and an area adjacent to the sub-pixels according to one or more modified (e.g., other or alternative) embodiments, respectively.

For convenience of description, in FIGS. 9 and 12-15, the first protective layer PVX1 is omitted (is not shown), and the conductive pattern layer CP patterned around the light emitting layer EL is shown. In FIGS. 10 and 11, a detailed illustration of some configurations are omitted (are not shown) similar to FIG. 8.

Referring to FIGS. 9-11, the light emitting layers EL of each of the sub-pixels SPX may have a certain shape, and the second protective layers PVX2 of each of the sub-pixels SPX may have different shapes according to the overlapping light emitting layers EL.

According to one or more embodiments, the formation range (e.g., formation area and/or position) of the interface between the second protective layers PVX2 and the optical adhesive layer PSA may be different according to a range (e.g., an area) in which the second protective layers PVX2 are formed. For example, a range in which the second protective layers PVX2 are formed may be adjusted, and thus a viewing angle characteristic may be improved in each of the sub-pixels SPX, thereby reducing a risk that output light information (optical information) is distorted.

For example, information on light output in a first side direction may be different from information on light output in a second side direction which is different from the first side direction in case that an aspect ratio of the light emitting layer EL (and/or the sub-pixel SPX) is different. For example, a color coordinate of light output in a left-right direction and a color coordinate of light output in an up-down direction from with respect to the light emitting layer EL in the sub-pixel SPX may be formed differently from each other.

In this case, there may exist a concern that color coordinate deviation of an image recognized according to a viewing angle for the display device DD may occur.

However, according to one or more embodiments, the second protective layer PVX2 may be patterned to compensate for a shape of the light emitting layer EL (or the sub-pixel SPX) to prevent or reduce light information distortion that may occur according to the shape of the light emitting layer EL (and/or the sub-pixel SPX). For example, the (2-1)-th protective layer PVX2-1, the (2-2)-th protective layer PVX2-2, and the (2-3)-th protective layer PVX2-3 may have different shapes.

Accordingly, a viewing angle characteristic for the display device DD may be improved, and a risk that color coordinate deviation and/or the like occurs according to a direction in which the display device DD is viewed may be reduced. As a result, according to one or more embodiments, the display device DD with excellent or suitable display quality and improved reliability of provided light information may be provided.

A structural characteristic of the second protective layer PVX2 and/or the like according to one or more embodiments is described in more detail herein below. Hereinafter, for convenience of description, the disclosure is described based on a structure of the first to third sub-pixels SPX1 to SPX3 (and/or the first to third light emitting layers EL1 to EL3), but it should be recognized that the display device DD according to one or more embodiments is not limited to the shape of the first to third sub-pixels SPX1 to SPX3 (and/or the first to third light emitting layers EL1 to EL3) shown in the drawings and/or the like.

According to one or more embodiments, the sub-pixels SPX may be arranged in a stripe structure (for example, an S-stripe structure). For example, the first and second sub-pixels SPX1 and SPX2 may be adjacent to the third sub-pixel SPX3 in the first direction DR1. The first and second sub-pixels SPX1 and SPX2 may be adjacent to each other in the second direction DR2. The first and second sub-pixel areas SPXA1 and SPXA2 may be adjacent to the third sub-pixel area SPXA3 in the first direction DR1. The first and second sub-pixel areas SPXA1 and SPXA2 may be adjacent to each other in the second direction DR2.

According to one or more embodiments, each of the light emitting layers EL may include a first side S1 and a second side S2. The first side S1 may refer to a side portion of the light emitting layer EL along the first direction DR1. The second side S2 may refer to a side portion of the light emitting layer EL along the second direction DR2. The first side S1 may be a side portion of the light emitting layer EL extending in the first direction DR1. The second side S2 may be a side portion of the light emitting layer EL extending in the second direction DR2.

The first direction DR1 and the second direction DR2 may be different from each other. For example, the first direction DR1 and the second direction DR2 may be normal (e.g., perpendicular or substantially perpendicular) to each other. However, the disclosure is not necessarily limited thereto.

The edge portion EDG may be formed adjacent to the first side S1 of the light emitting layer EL in embodiments in which the first side S1 of the light emitting layer EL is longer than the second side S2 of the light emitting layer EL.

For example, the first light emitting layer EL1 of the first sub-pixel SPX1 may have a shape extending in the first direction DR1. For example, the first side S1 of the first light emitting layer EL1 may extend longer than the second side S2 of the first light emitting layer EL1.

The first edge portion EDG1 may be adjacent to the first side S1 of the first light emitting layer EL1 in a plan view. The first edge portion EDG1 may be adjacent to the first light emitting layer EL1 in the second direction DR2 in a plan view.

The first light emitting layer EL1 may protrude in the first direction DR1 with respect to the (2-1)-th protective layer PVX2-1 in a plan view. In a plan view, a portion of the first light emitting layer EL1 which does not overlap the (2-1)-th protective layer PVX2-1 may be adjacent to the (2-1)-th protective layer PVX2-1 in the first direction DR1.

In this case, the first edge portion EDG1 may increase an amount of light extracted from the first light emitting layer EL1 in upper and lower directions, and a color coordinate deviation in upper and lower sides and left and right sides due to a shape of the first light emitting layer EL1 may be compensated or substantially compensated.

In this specification, the upper direction and the lower direction may be directions substantially parallel to the second direction DR2, and may refer to opposite directions, respectively, and the left direction and the right direction may be directions substantially parallel to the first direction DR1, and may refer to opposite directions, respectively.

The edge portion EDG may be formed adjacent to each of the first side S1 and the second side S2 of the light emitting layer EL in embodiments in which the first side S1 of the light emitting layer EL and the second side S2 of the light emitting layer EL have lengths similar to each other (for example, substantially the same length).

For example, the second light emitting layer EL2 of the second sub-pixel SPX2 may have sides extending to (e.g., sides of) the same length in a plan view. For example, the second light emitting layer EL2 may have a regular polygonal shape. The second light emitting layer EL2 may have a square shape. The first side S1 of the second light emitting layer EL2 and the second side S2 of the second light emitting layer EL2 may have the same length.

The second edge portion EDG2 may be adjacent to each of the first side S1 and the second side S2 of the second light emitting layer EL2 in a plan view. The second edge portion EDG2 may be adjacent to the second light emitting layer EL2 in the first direction DR1 and the second direction DR2 in a plan view.

The second light emitting layer EL2 may be entirely covered by the (2-2)-th protective layer PVX2-2 in a plan view. In this case, a range in which light is extracted by the second edge portion EDG2 may be expanded.

The edge portion EDG may be formed adjacent to the second side S2 of the light emitting layer EL in case that the second side S2 of the light emitting layer EL is longer than the first side S1 of the light emitting layer EL.

For example, the third light emitting layer EL3 of the third sub-pixel SPX3 may have a shape extending in the second direction DR2. For example, the second side S2 of the third light emitting layer EL3 may extend longer than the first side S1 of the third light emitting layer EL3.

The third edge portion EDG3 may be adjacent to the second side S2 of the third light emitting layer EL3 in a plan view. The third edge portion EDG3 may be adjacent to the third light emitting layer EL3 in the first direction DR1 in a plan view.

The third light emitting layer EL3 may protrude in the second direction DR2 with respect to the (2-3)-th protective layer PVX2-3 in a plan view. In a plan view, a portion of the third light emitting layer EL3 which does not overlap the (2-3)-th protective layer PVX2-3 may be adjacent to the (2-3)-th protective layer PVX2-3 in the second direction DR2.

In this case, the third edge portion EDG3 may increase an amount of light extracted from the third light emitting layer EL3 in the left and right directions, and a color coordinate deviation in the upper and lower sides and the left and right sides due to a shape of the third light emitting layer EL3 may be compensated or substantially compensated.

In FIGS. 12-15, some modified embodiments compared to one or more embodiments described above are shown.

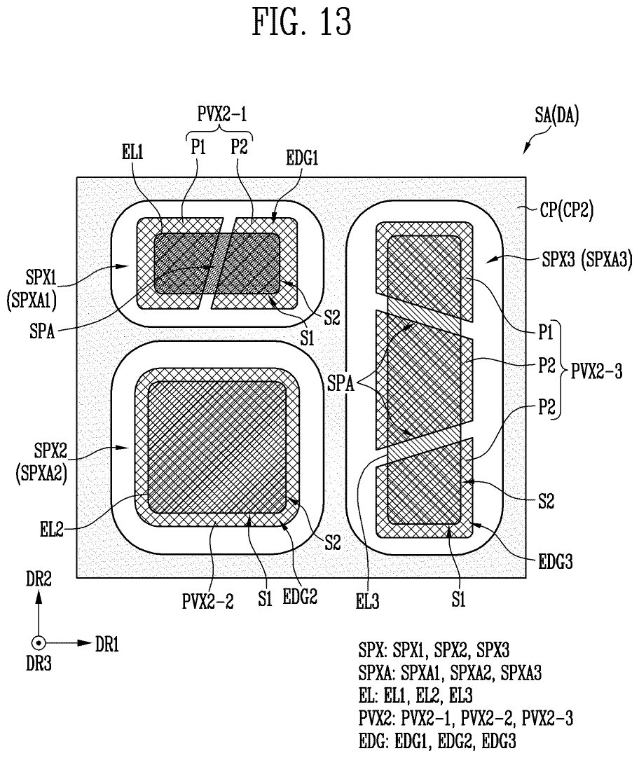

Referring to FIGS. 12 and 13, the display device(s) DD according to some embodiments is different from the embodiments described above, in that the second protective layer PVX2 includes a plurality of pieces in a portion of the sub-pixels SPX.

For example, the second protective layer PVX2 may be formed as a plurality of pieces in the first and third sub-pixels SPX1 and SPX3. The second protective layer PVX2 may be formed as a single piece in the second sub-pixel SPX2.

According to one or more embodiments, the (2-1)-th protective layer PVX2-1 may include a plurality of portions. For example, the (2-1)-th protective layer PVX2-1 may include a first portion P1 and a second portion P2 spaced and/or apart (e.g., spaced apart or separated) from each other in the first direction DR1. According to one or more embodiments, the number of portions forming the second protective layer PVX2 in the first and third sub-pixels SPX1 and SPX3 is not limited to the example described above.

According to one or more embodiments, the first portion P1 and the second portion P2 of the (2-1)-th protective layer PVX2-1 may be spaced and/or apart (e.g., spaced apart or separated) from each other with a separation area SPA between the first portion P1 and the second portion P2. According to an example (refer to FIG. 12), the first portion P1 and the second portion P2 of the (2-1)-th protective layer PVX2-1 may each have an approximately rectangular shape, and the separation area SPA may have a shape extending in the second direction DR2. In one or more embodiments, in another example (refer to FIG. 13), the first portion P1 and the second portion P2 of the (2-1)-th protective layer PVX2-1 may each have an approximately or substantial trapezoidal shape (e.g., parallelogram shape), and the separation area SPA may have a shape extending in a diagonal direction (for example, a first diagonal direction) between the first direction DR1 and the second direction DR2. The above-described diagonal direction may be approximately 45 degrees relative to the first direction DR1, but the disclosure is not limited thereto. Alternatively, the separation area SPA may extend at other angles, such as about 30 degrees, about 60 degrees, or even about 90 degrees, depending on the specific design requirements. However, the disclosure is not limited to these angles.

According to one or more embodiments, the (2-3)-th protective layer PVX2-3 may include a plurality of portions. For example, the (2-3)-th protective layer PVX2-3 may include a first portion P1, a second portion P2, and a third portion P3 spaced and/or apart (e.g., spaced apart or separated) from each other in the second direction DR2.

According to one or more embodiments, each of the first portion P1, the second portion P2, and the third portion P3 of the (2-3)-th protective layer PVX2-3 may be spaced and/or apart (e.g., spaced apart or separated) from each other with a separation area SPA between the first portion P1, the second portion P2, and the third portion P3. According to an example (refer to FIG. 12), the first portion P1, the second portion P2, and the third portion P3 of the (2-3)-th protective layer PVX2-3 may each have an approximately rectangular shape, and the separation area SPA may have a shape extending in the first direction DR1. In one or more embodiments, in another example (refer to FIG. 13), the first portion P1, the second portion P2, and the third portion P3 of the (2-3)-th protective layer PVX2-3 may each have an approximately trapezoidal shape, and the separation area SPA may have a shape extending in the diagonal direction between the first direction DR1 and the second direction DR2. The above-described diagonal direction (for example, a second diagonal direction) may be approximately 45 degrees relative to the first direction DR1, but the disclosure is not limited thereto. Alternatively, the separation area SPA may extend at other angles, such as about 30 degrees, about 60 degrees, or even about 90 degrees, depending on the specific design requirements. However, the disclosure is not limited to these angles. According to one or more embodiments, the separation area SPA for the (2-3)-th protective layer PVX2-3 may include a first separation area extending in a diagonal direction (e.g., a 2 o'clock direction and/or a direction corresponding to an approximately 45 degree angle relative to the first direction DR1) and a second separation area extending in a diagonal direction (e.g., a 10 o'clock direction and/or a direction corresponding to an approximately 135 degree angle relative to the first direction DR1).

According to one or more embodiments, in the first and third sub-pixels SPX1 and SPX3, the second protective layer PVX2 may be formed in a plurality of pieces, and the edge portion EDG may be formed adjacent to the first side S1 of the light emitting layer EL and may also be formed adjacent to the second side S2 of the light emitting layer EL.

In this case, an output path of the light provided from the light emitting layer EL may be formed based on an area where the edge portion EDG is arranged.

For example, the first edge portion EDG1 may not be formed in at least a portion of the first side S1 of the first light emitting layer EL1. For example, a light extraction amount output toward the first side S1 may be relatively decreased, and a light extraction amount output toward the second side S2 may be relatively increased. Accordingly, occurrence of a light extraction amount deviation and/or a color coordinate deviation for each direction of light output in the first sub-pixel SPX1 may be reduced.

For example, the third edge portion EDG3 may not be formed in at least a portion of the second side S2 of the third light emitting layer EL3. For example, a light extraction amount output toward the second side S2 may be relatively decreased, and a light extraction amount output toward the first side S1 may be relatively increased. Accordingly, occurrence of a light extraction amount deviation and/or a color coordinate deviation for each direction of light output in the third sub-pixel SPX3 may be reduced.

According to the present embodiments, a risk that display quality may be deteriorated according to the shape of the light emitting layer EL (or the sub-pixel SPX) may be substantially reduced.

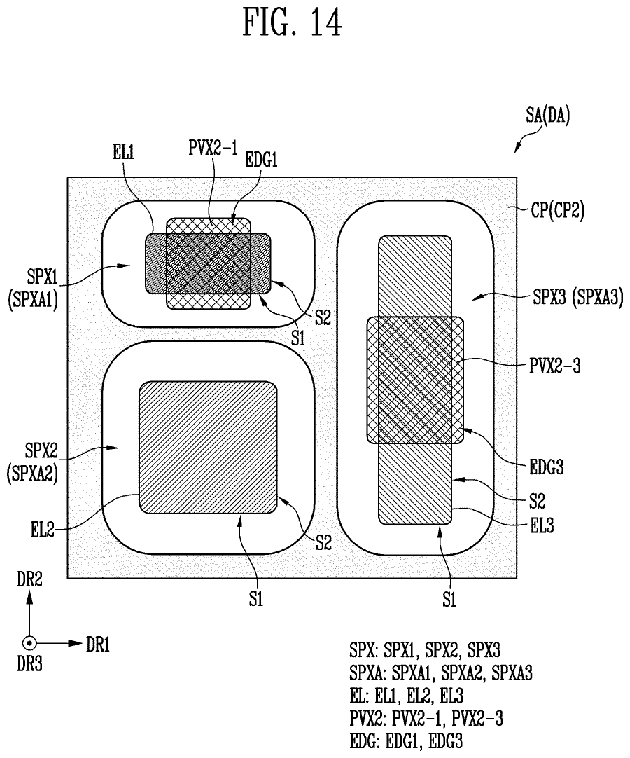

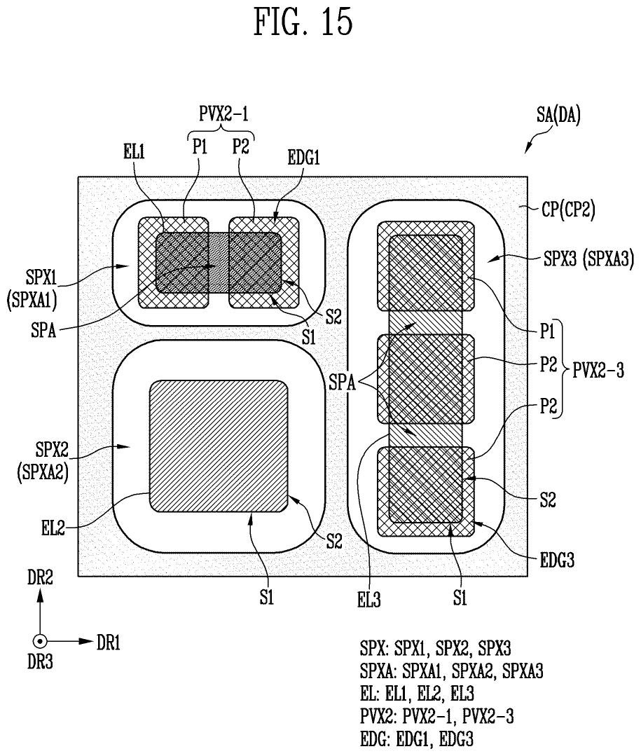

Referring to FIGS. 14 and 15, the display device DD according to one or more embodiments is different from one or more embodiments described above, in that the protective layer PVX is not formed in the second sub-pixel SPX2.

According to this embodiment, the protective layer PVX may be formed in the first and third sub-pixels SPX1 and SPX3, and may not be formed in the second sub-pixel SPX2. The second protective layer PVX2 may not overlap the second light emitting layer EL2 in a plan view.

For example (refer to FIG. 14), a (2-1)-th protective layer PVX2-1 may be formed in the first sub-pixel SPX1, a (2-3)-th protective layer PVX2-3 may be formed in the third sub-pixel SPX3, and the second protective layer PVX2 may not be formed on the second light emitting layer EL2.

For example (refer to FIG. 15), the (2-1)-th protective layer PVX2-1 including a plurality of portions may be formed in the first sub-pixel SPX1, the (2-3)-th protective layer PVX2-3 including a plurality of portions may be formed in the third sub-pixel SPX3, and the second protective layer PVX2 may not be formed on the second light emitting layer EL2.

According to this embodiment, the second protective layer PVX2 may not be located in the second sub-pixel SPX2 where the first side S1 and the second side S2 have substantially the same length. Accordingly, light provided from the second sub-pixel SPX2 may have a similar color coordinate for each of observed directions, and a placement of the second protective layer PVX2 may not be provided. In this case, a front light output efficiency for the second sub-pixel SPX2 may be further secured and/or improved.

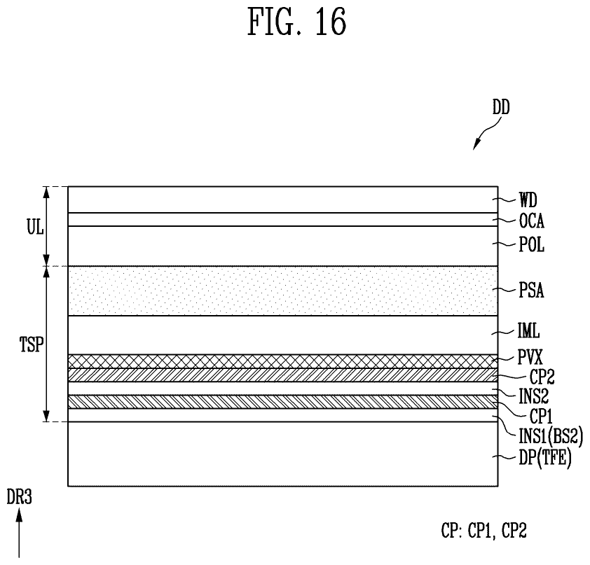

With reference to FIGS. 16-26, a display device DD according to one or more embodiments is described. For convenience of description, a content that may overlap the content described above is briefly described or is not repeated.

The display device(s) DD of FIGS. 16-26 according to embodiments are different from the display device DD according to one or more embodiments described above, in that the second protective layer PVX2 is not formed and the display device DD further includes an intermediate layer IML that may form an interface converting a light path.

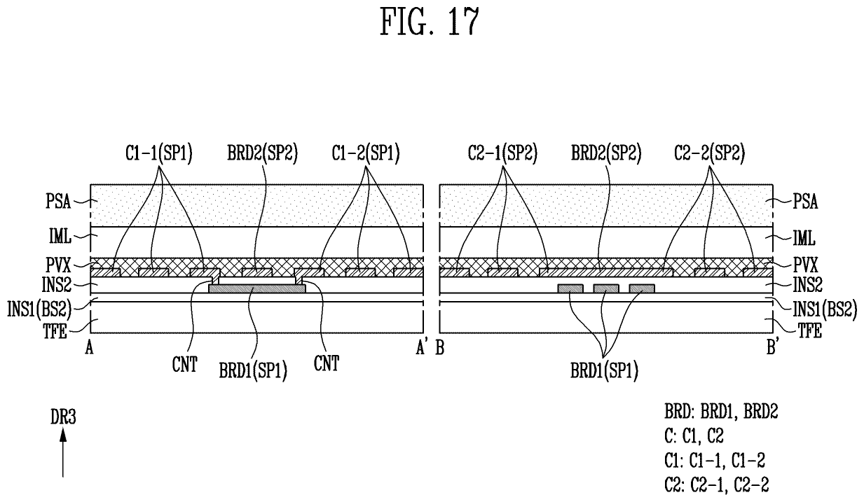

FIG. 16 is a schematic cross-sectional view illustrating a sensor layer according to one or more embodiments. FIG. 17 is a schematic cross-sectional view illustrating a sensor layer and an upper layer according to one or more embodiments. For convenience of description, FIG. 17 schematically shows a cross-sectional structure corresponding to the area described above with reference to FIG. 6. For example, FIG. 17 schematically illustrates one or more embodiments of a cross-sectional structure according to A˜A′ (e.g., cut along the A˜A′ line) of FIG. 5 and a cross-sectional structure according to B˜B′ (e.g., cut along the B˜B′ line) of FIG. 6.

Referring to FIGS. 16 and 17, the display device DD may further include the intermediate layer IML.

The intermediate layer IML may be located (for example, directly located) on the protective layer PVX. The intermediate layer IML may be located between the protective layer PVX and the optical adhesive layer PSA. The intermediate layer IML may have a thicker thickness compared to the protective layer PVX. According to one or more embodiments, the intermediate layer IML may be included in the sensor layer TSP. The intermediate layer IML may be located across the sub-pixel areas SPXA.

The intermediate layer IML may include one or more suitable insulating materials. For example, the intermediate layer IML may include an organic material and/or an inorganic material. For example, the intermediate layer IML may include one or more selected from among an acrylic resin, an epoxy resin, a phenol resin, a polyamide resin, a polyimide resin, a methacrylic resin, a polyisoprene resin, a vinyl resin, a urethane resin, a cellulose resin, a siloxane resin, and a perylene resin. The intermediate layer IML may further include an inorganic material. For example, the intermediate layer IML may further include zirconium oxide (ZrxOy). However, the disclosure is not limited thereto.

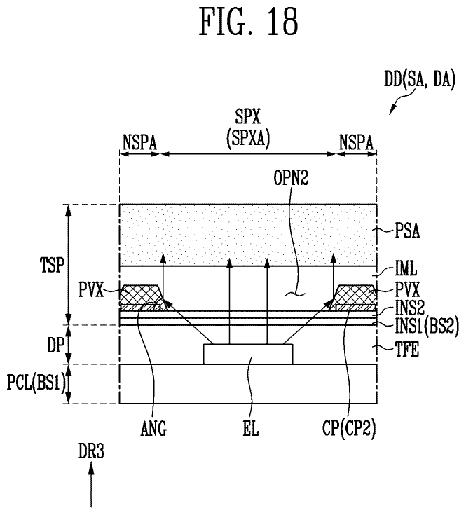

The intermediate layer IML may form an interface with the protective layer PVX. According to one or more embodiments, light provided from the display layer DP (for example, the light emitting element LD) may be refracted at the interface between the intermediate layer IML and the protective layer PVX, and the display device DD may provide the light to the outside along an intended (e.g., set) path. A content related to this is described in more detail herein below with reference to FIG. 18 and subsequent drawings.

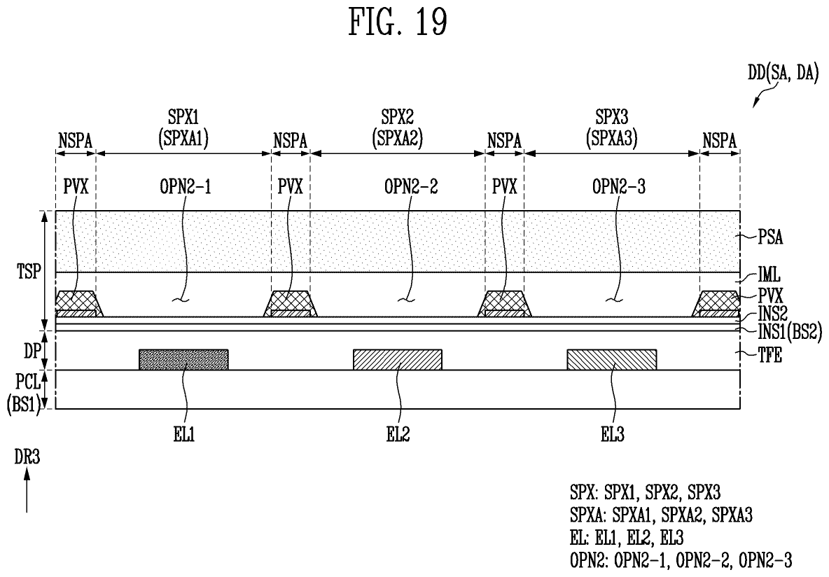

FIGS. 18 and 19 are schematic cross-sectional views each illustrating a display device according to one or more embodiments. FIG. 18 schematically shows a partial cross-sectional structure of a display device DD forming a sub-pixel SPX according to one or more embodiments. FIG. 18 schematically shows a light path of the light provided by the light emitting layer EL. For example, the light path of the light provided by the light emitting layer EL is expressed by an arrow. FIG. 19 schematically shows a partial cross-sectional structure of a display device DD forming first to third sub-pixels SPX1 to SPX3 according to one or more embodiments. For convenience of description, in FIGS. 18 and 19, some configurations are not provided similar to FIGS. 7 and 8.

Referring to FIGS. 18 and 19, the light provided by the light emitting layer EL may be transmitted through the intermediate layer IML and the optical adhesive layer PSA and may be provided to the outside of the display device DD along a light path.

The protective layer PVX may not be located in an area overlapping the light emitting layer EL in a plan view. The protective layer PVX may expose at least a portion of the second insulating layer INS2 in the sub-pixel area SPXA. The protective layer PVX may entirely cover the conductive pattern layer CP. For example, the protective layer PVX may entirely cover the second conductive pattern layer CP2.

The protective layer PVX may be around (e.g., may surround) an area in a plan view. The protective layer PVX may form an optical opening OPN2. The protective layers PVX located in the non-sub-pixel area NSPA may be adjacent to each other with the optical opening OPN2 between the protective layers PVX.

At least a portion of the intermediate layer IML may be provided in the optical opening OPN2. For example, at least a portion of the intermediate layer IML may fill the optical opening OPN2. The intermediate layer IML may contact a portion of the second insulating layer INS2 exposed through the optical opening OPN2.

A position of the optical opening OPN2 may correspond to the sub-pixel SPX (for example, the sub-pixel area SPXA). At least a portion of the optical opening OPN2 may be located in the sub-pixel area SPXA. The optical opening OPN2 may overlap the light the emitting layer EL in a plan view.

The optical opening OPN2 may include a first optical opening OPN2-1 formed in the first sub-pixel area SPXA1 and overlapping the first light emitting layer EL1, a second optical opening OPN2-2 formed in the second sub-pixel area SPXA2 and overlapping the second light emitting layer EL2, and a third optical opening OPN2-3 formed in the third sub-pixel area SPXA3 and overlapping the third light emitting layer EL3.

The protective layer PVX and the intermediate layer IML may be in contact with each other. According to one or more embodiments, the interface formed by the protective layer PVX and the intermediate layer IML may extend in the diagonal direction (for example, the direction different from the third direction DR3) in an area adjacent to the optical opening OPN2.

For example, a side surface of the protective layer PVX may form an angle ANG with respect to a plane where the first base layer BS1 is arranged. The angle ANG may be an acute angle, and thus the side surface of the protective layer PVX directly adjacent to the intermediate layer IML located in the sub-pixel area SPXA and overlapping the light emitting layer EL may form a tapered surface in a forward (e.g., upward) direction.

The intermediate layer IML may have a refractive index (for example, a third refractive index) greater than the refractive index of the protective layer PVX. For example, the refractive index of the protective layer PVX may be in a range of 1.50 to 1.58. According to one or more embodiments, the protective layer PVX may have a refractive index of about 1.54. However, the disclosure is not limited thereto. For example, the refractive index of the intermediate layer IML may be in a range of 1.58 to 1.62. According to one or more embodiments, the intermediate layer IML may have a refractive index of about 1.6. However, the disclosure is not limited thereto.

According to one or more embodiments, at least a portion of the light provided by the light emitting layer EL may be transmitted through the intermediate layer IML and the optical adhesive layer PSA. For example, the light emitting layer EL may overlap a portion of the intermediate layer IML in the optical opening OPN2 in a plan view, and the light emitted by the light emitting layer EL may be transmitted through the optical adhesive layer PSA through the intermediate layer IML, and may be recognized (e.g., may be seen) from the front surface of the display device DD.

According to one or more embodiments, a portion of the light provided by the light emitting layer EL may be totally reflected at the interface between the protective layer PVX and the intermediate layer IML and may be transmitted through the optical adhesive layer PSA. For example, as at least a portion of the light emitted by the light emitting layer EL, a portion of the emitted light opposite to (e.g., facing) the diagonal direction (for example, the direction different from the third direction DR3) may be provided at the interface between the protective layer PVX and the intermediate layer IML. At this time, due to a refractive index difference between the protective layer PVX and the intermediate layer IML, the provided light may be totally reflected and guided to the display direction (for example, the third direction DR3) of the display device DD. Accordingly, light emission efficiency of the light emitting element LD may be improved, and power desired or required to implement an image with the same (e.g., a set or predetermined suitable) luminance may be reduced. For example, according to one or more embodiments, the display device DD with improved light output efficiency may be provided.

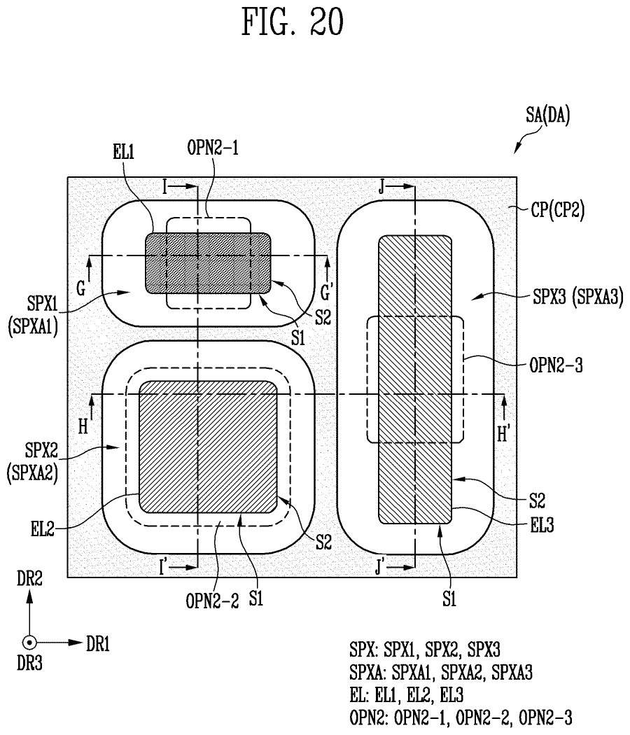

According to one or more embodiments, a formation range (e.g., positioned, size and/or width) of the optical opening OPN2 may be adjusted, and thus a range in which the intermediate layer IML forming the interface with the protective layer PVX is arranged may be adjusted, and thus a viewing angle characteristic for each of the sub-pixels SPX may be improved. This is described in more detail hereinbelow with reference to FIGS. 20-26.

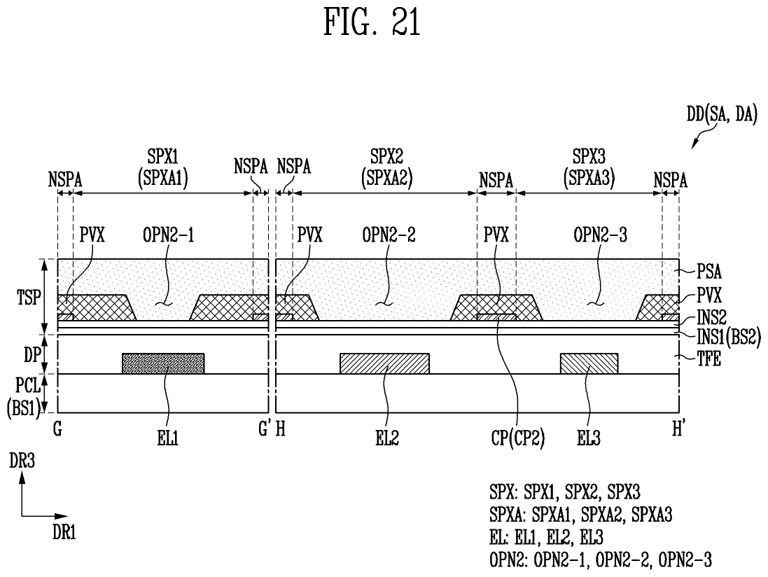

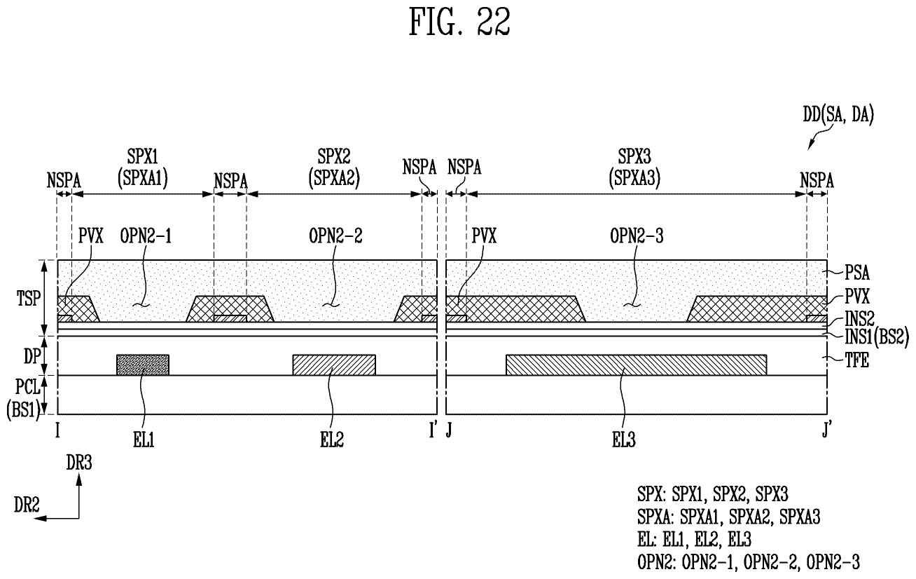

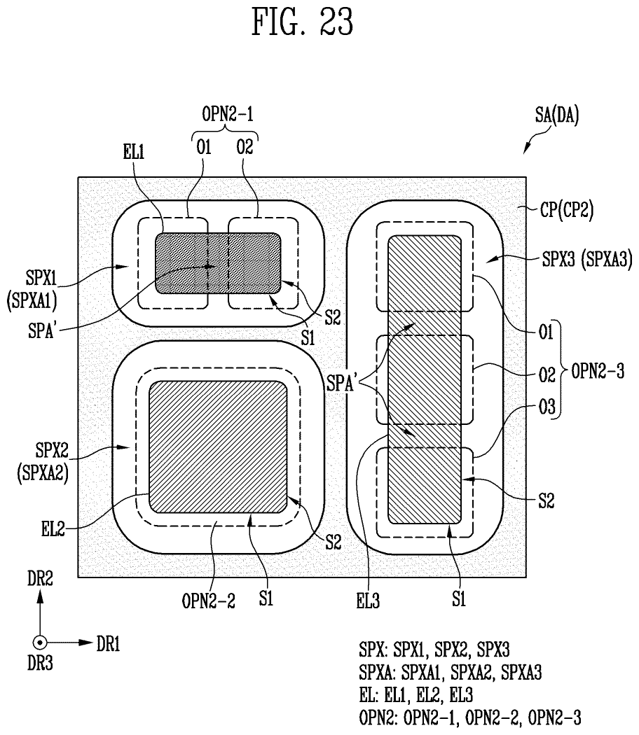

FIG. 20 is a schematic plan view illustrating sub-pixels and an area adjacent to the sub-pixels according to one or more embodiments. FIGS. 21 and 22 are schematic cross-sectional views illustrating a display device according to one or more embodiments. FIG. 21 is a schematic cross-sectional view taken along the line G˜G′ of FIG. 20 and a schematic cross-sectional view taken along the line H˜H′ of FIG. 20. FIG. 22 is a schematic cross-sectional view taken along the line I˜I′ of FIG. 20 and a schematic cross-sectional view taken along the line J˜J′ of FIG. 20. FIGS. 23-26 are schematic plan views illustrating sub-pixels and an area adjacent to the sub-pixels according to modified (e.g., other or alternative) embodiments, respectively.

For convenience of description, in FIGS. 20 and 23-26, the intermediate layer IML and the protective layer PVX are not shown, and the conductive pattern layer CP patterned around the light the emitting layer EL is shown. In FIGS. 20 and 23-26, a position of the optical opening OPN2 is indicated by a dotted line range. The interface between the intermediate layer IML and the protective layer PVX, through which light may be refracted may be formed at an edge of the optical opening OPN2. Accordingly, based on a position of the optical opening OPN2 indicated in FIGS. 20 and 23-26, a location range of the protective layer PVX, a location range of the intermediate layer IML formed in the optical opening OPN2 may be clearly understood. In FIGS. 21 and 22, a detailed illustration of some configurations is not provided similar to FIG. 8.

Referring to FIGS. 20 to 22, the light emitting layers EL of each of the sub-pixels SPX may have a certain shape, and the optical opening OPN2 of each of the sub-pixels SPX may be formed in different ranges (e.g., at one or more suitable positions and/or in one or more suitable shapes) according to the overlapping light emitting layers EL.

According to one or more embodiments, a formation range of the interface between the protective layer PVX and the intermediate layer IML may be different according to a range in which the optical opening OPN2 is formed. For example, the range (e.g., the area) in which the optical opening OPN2 is formed may be adjusted, and thus a viewing angle characteristic may be improved in each of the sub-pixels SPX, thereby reducing a risk that output light information is distorted.

According to one or more embodiments, the optical opening OPN2 may be formed to compensate for the shape of the light emitting layer EL (and/or the sub-pixel SPX) to prevent or reduce light information distortion that may occur according to the shape of the light emitting layer EL (and/or the sub-pixel SPX). For example, the first optical opening OPN2-1, the second optical opening OPN2-2, and the third optical opening OPN2-3 may have different shapes.

Accordingly, a viewing angle characteristic for the display device DD may be improved, and a risk of occurrence of a color coordinate deviation and/or the like according to a direction in which the display device DD is viewed may be reduced. As a result, according to one or more embodiments, the display device DD with excellent or suitable display quality and improved reliability of provided light information may be provided.

For example, according to one or more embodiments, the optical opening OPN2 may be formed to compensate for the shape of the light-emitting layer EL (and/or the sub-pixel SPX) to prevent or reduce light information distortion that may occur due to the shape of the light-emitting layer EL (and/or the sub-pixel SPX). For example, the first optical opening OPN2-1, the second optical opening OPN2-2, and the third optical opening OPN2-3 may have different shapes. Consequently, the viewing angle characteristic for the display device DD may be improved, and the risk of color coordinate deviation and similar issues according to the direction in which the display device DD is viewed may be reduced. As a result, according to one or more embodiments, a display device DD with enhanced (e.g., excellent or suitable) display quality and enhanced (e.g., improved) reliability of provided light information may be achieved.

Structural characteristics of the optical opening OPN2 according to one or more embodiments are described in more detail herein below.

At least a portion of the optical opening OPN2 may be formed to extend from the first side S1 of the light emitting layer EL in the second direction DR2 in embodiments in which the first side S1 of the light emitting layer EL is longer than the second side S2 of the light emitting layer EL.

For example, the first light emitting layer EL1 of the first sub-pixel SPX1 may have a shape extending in the first direction DR1. For example, the first side S1 of the first light emitting layer EL1 may extend longer than the second side S2 of the first light emitting layer EL1.

At least a portion of the first optical opening OPN2-1 may not overlap the first light emitting layer EL1 in a plan view, and at least a portion of the first optical opening OPN2-1 which does not overlap the first light emitting layer EL1 may be adjacent to the first side S1 of the first light emitting layer EL1 in a plan view. At least a portion of the first optical opening OPN2-1 which does not overlap the first light emitting layer EL1 may be adjacent to the first light emitting layer EL1 in the second direction DR2 in a plan view.

The first light emitting layer EL1 may protrude in the first direction DR1 with respect to the first optical opening OPN2-1 in a plan view. In a plan view, a portion of the first light emitting layer EL1 which does not overlap the first optical opening OPN2-1 may be adjacent to the first optical opening OPN2-1 in the first direction DR1.

In this case, the first optical opening OPN2-1 may increase an amount of light extracted from the first light emitting layer EL1 in the upper and lower directions, and a color coordinate deviation in the upper and lower sides and the left and right sides due to a shape of the first light emitting layer EL1 may be compensated or reduced.

The optical opening OPN2 may be formed to protrude from each of the first side S1 and the second side S2 of the light emitting layer EL in embodiments in which the first side S1 of the light emitting layer EL and the second side S2 of the light emitting layer EL have lengths similar to each other (for example, substantially the same length).

For example, the second light emitting layer EL2 of the second sub-pixel SPX2 may have sides extending in (e.g., of) the same length in a plan view. For example, the second light emitting layer EL2 may have a regular polygonal shape. The second light emitting layer EL2 may have a square shape. The first side S1 of the second light emitting layer EL2 and the second side S2 of the second light emitting layer EL2 may have the same length.

The second optical opening OPN2-2 may be adjacent to the first side S1 and the second side S2 of the second light emitting layer EL2 in a direction opposite to (e.g., facing) outward in a plan view.

The second light emitting layer EL2 may be entirely covered by the second optical opening OPN2-2 in a plan view. In this case, a range in which light is extracted by the second optical opening OPN2-2 may be expanded.

At least a portion of the optical opening OPN2 may be formed to extend from the second side S2 of the light emitting layer EL in the first direction DR1 in embodiments in which the second side S2 of the light emitting layer EL is longer than the first side S1 of the light emitting layer EL.

For example, the third light emitting layer EL3 of the third sub-pixel SPX3 may have a shape extending in the second direction DR2. For example, the second side S2 of the third light emitting layer EL3 may extend longer than the first side S1 of the third light emitting layer EL3.

At least a portion of the third optical opening OPN2-3 may not overlap the third light emitting layer EL3 in a plan view, and at least a portion of the third optical opening OPN2-3 which does not overlap the third light emitting layer EL3 may be adjacent to the second side S2 of the third light emitting layer EL3 in a plan view. At least a portion of the third optical opening OPN2-3 which does not overlap the third light emitting layer EL3 may be adjacent to the third light emitting layer EL3 in the first direction DR1 in a plan view.

The third light emitting layer EL3 may protrude in the second direction DR2 with respect to the third optical opening OPN2-3 in a plan view. In a plan view, a portion of the third light emitting layer EL3 which does not overlap the third optical opening OPN2-3 may be adjacent to the third optical opening OPN2-3 in the second direction DR2.

In this case, the third optical opening OPN2-3 may increase an amount of light extracted from the third light emitting layer EL3 in the left and right directions, and a color coordinate deviation in the upper and lower sides and the left and right sides due to a shape of the third light emitting layer EL3 may be compensated or reduced.

FIGS. 23-26 show some modified embodiments compared to the one or more embodiments described above.

Referring to FIG. 23, a display device DD according to one or more embodiments is different from one or more embodiments described above, in that the optical opening OPN2 is formed in a plurality of pieces in a portion of the sub-pixels SPX.

For example, the optical opening OPN2 may be formed as a plurality of pieces in the first and third sub-pixels SPX1 and SPX3. The optical opening OPN2 may be formed as a single piece in the second sub-pixel SPX2.

According to one or more embodiments, the optical opening OPN2 may include a plurality of portions. For example, the first optical opening OPN2-1 may include a first optical portion O1 and a second optical portion O2 spaced and/or apart (e.g., spaced apart or separated) from each other in the first direction DR1. According to one or more embodiments, the number of portions forming the first optical opening OPN2-1 in the first sub-pixel SPX1 is not limited to the above-described example.

According to one or more embodiments, the first optical portion O1 and the second optical portion O2 of the first optical opening OPN2-1 may be spaced and/or apart (e.g., spaced apart or separated) from each other with a separation area SPA′ between the first optical portion O1 and the second optical portion O2. According to some embodiments, the first optical portion O1 and the second optical portion O2 of the first optical opening OPN2-1 may have an approximately rectangular shape, and the separation area SPA′ may have a shape extending in the second direction DR2.

According to one or more embodiments, the third optical opening OPN2-3 may include a plurality of portions. For example, the third optical opening OPN2-3 may include a first optical portion O1, a second optical portion O2, and a third optical portion O3 spaced and/or apart (e.g., spaced apart or separated) from each other in the second direction DR2.

According to one or more embodiments, each of the first optical portion O1, the second optical portion O2, and the third optical portion O3 of the third optical opening OPN2-3 may be spaced and/or apart (e.g., spaced apart or separated) from each other with the separation area SPA′ between the first optical portion O1, the second optical portion O2, and the third optical portion O3. According to an example, the first optical portion O1, the second optical portion O2, and the third optical portion O3 of the third optical opening OPN2-3 may have an approximately rectangular shape, and the separation area SPA′ may have a shape extending in the first direction DR1.

According to one or more embodiments, in the first and third sub-pixels SPX1 and SPX3, the optical opening OPN2 may be formed as a plurality of pieces, and portions of the optical openings OPN2 which do not overlap the light emitting layer EL may be formed adjacent to the first side S1 of the light emitting layer EL and may also be formed adjacent to the second side S2 of the light emitting layer EL.

In this case, an output path of the light provided from the light emitting layer EL may be formed based on an area of portions of the optical opening OPN2 which does not overlap the light emitting layer EL.

For example, the first optical opening OPN2-1 may not be formed in at least a portion of the first side S1 of the first light emitting layer EL1. For example, a light extraction amount output toward the first side S1 may be relatively decreased, and a light extraction amount output toward the second side S2 may be relatively increased. Accordingly, occurrence of a light extraction amount deviation and a color coordinate deviation for each direction of light output from the first sub-pixel SPX1 may be reduced.

For example, the third optical opening OPN2-3 may not be formed in at least a portion of the second side S2 of the third light emitting layer EL3. For example, a light extraction amount output toward the second side S2 may be relatively decreased, and a light extraction amount output toward the first side S1 may be relatively increased. Accordingly, occurrence of a light extraction amount deviation and a color coordinate deviation for each direction of light output from the third sub-pixel SPX3 may be reduced.

As a result, a risk that display quality may be deteriorated according to (e.g., due to) the shape of the light emitting layer EL (and/or the sub-pixel SPX) may be substantially reduced in the display device according to these embodiments.

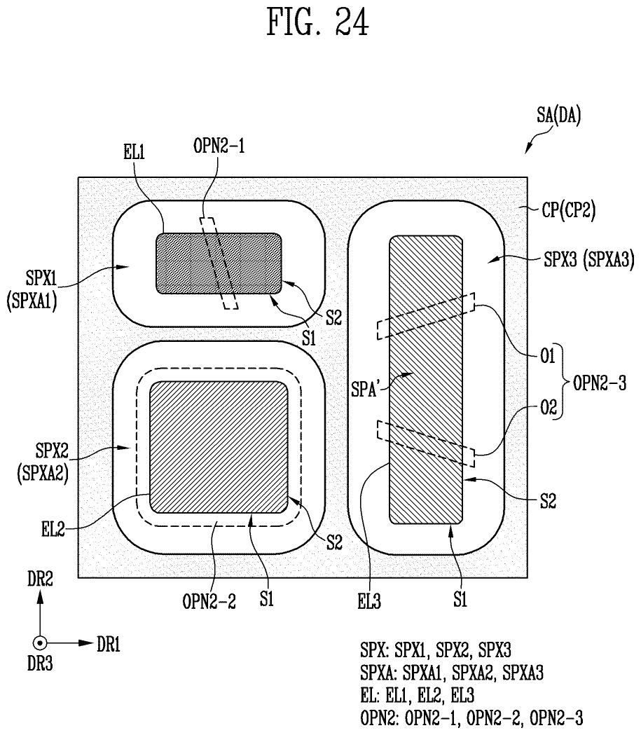

Referring to FIG. 24, a display device DD according to one or more embodiments is different from one or more embodiments described above, in that the optical opening OPN2 has a relatively thin width extending in a direction in a portion of the sub-pixels SPX.

For example, the optical opening OPN2 may have a shape extending in a direction in the first and third sub-pixels SPX1 and SPX3.

According to one or more embodiments, the (2-1)-th optical opening OPN2-1 may generally extend in a diagonal direction adjacent to the second direction DR2. For example, the (2-1)-th optical opening OPN2-1 may have a trapezoidal shape. At least a portion of the (2-1)-th optical opening OPN2-1 may protrude in an area adjacent to the first side S1. Accordingly, the (2-1)-th optical opening OPN2-1 may increase a light extract amount in the upper and lower sides among light provided from the first light emitting layer EL1, thereby preventing or reducing occurrence of a color coordinate deviation for the first sub-pixel SPX1. According to one or more embodiments, a direction in which the (2-1)-th optical opening OPN2-1 extends may be a diagonal direction, and may be approximately (about) 45 degrees with respect to the first direction DR1. However, the disclosure is not limited thereto. For example, the direction in which the (2-1)-th optical opening OPN2-1 extends may be diagonal and about 45 degrees with respect to the first direction DR1. Alternatively, the (2-1)-th optical opening OPN2-1 may extend at other angles, such as about 30 degrees, about 60 degrees, or even about 90 degrees, depending on the specific design requirements. However, the disclosure is not limited to these angles.

According to one or more embodiments, the (2-3)-th optical opening OPN2-3 may extend in a diagonal direction adjacent to the second direction DR2. For example, the (2-3)-th optical opening OPN2-3 may have a trapezoidal shape (e.g., parallelogram shape). At least a portion of the (2-3)-th optical opening OPN2-3 may protrude in an area adjacent to the second side S2. Accordingly, the (2-3)-th optical opening OPN2-3 may increase a light extract amount opposite to (e.g., facing) the left and right directions among light provided from the third light emitting layer EL3, thereby preventing or reducing occurrence of a color coordinate deviation for the third sub-pixel SPX3. According to one or more embodiments, a direction in which the (2-3)-th optical opening OPN2-3 extends may be a diagonal direction and may be approximately 45 degrees with respect to the first direction DR1. However, the disclosure is not limited thereto. According to one or more embodiments, the (2-3)-th optical opening OPN2-3 may include first and second optical portions O1 and O2 spaced and/or apart (e.g., spaced apart or separated) from each other with the separation area SPA′ between the first and second optical portions O1 and O2 along the second direction DR2. However, the disclosure is not limited thereto. For example, the (2-3)-th optical openings OPN2-3 may include three or more optical portions, and/or may include a different suitable optical portion. For example, the (2-3)-th optical openings OPN2-3 may include three or more optical portions, or may include an optical portion with a different configuration (e.g., various suitable shapes, sizes, or arrangements).

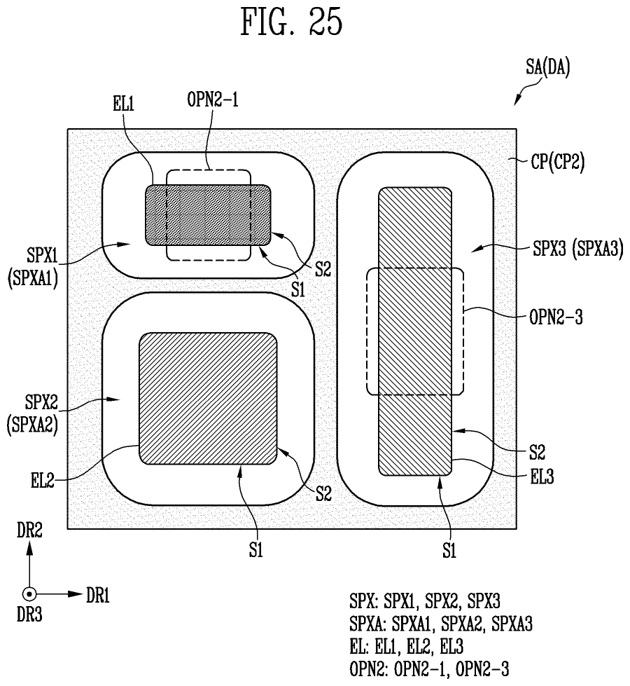

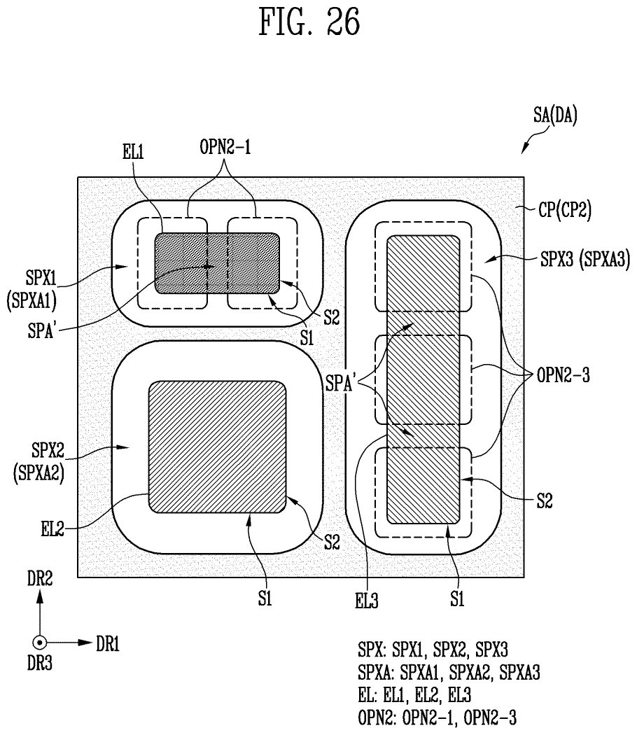

Referring to FIGS. 25 and 26, a display device DD according to one or more embodiments is different from one or more embodiments described above, in that the optical opening OPN2 is not formed in the second sub-pixel SPX2.

According to this embodiment, the optical opening OPN2 may be formed in the first and third sub-pixels SPX1 and SPX3, and may not be formed in the second sub-pixel SPX2. The protective layer PVX may entirely cover the light emitting layer EL in a plan view.

For example (refer to FIG. 25), a first optical opening OPN2-1 may be formed in the first sub-pixel SPX1, a third optical opening OPN2-3 may be formed in the third sub-pixel SPX3, and the optical opening OPN2 may not be formed on the second light emitting layer EL2.

For example (refer to FIG. 26), a plurality of first optical openings OPN2-1 may be formed in the first sub-pixel SPX1, a plurality of third optical openings OPN2-3 may be formed in the third sub-pixel SPX3, and the optical opening OPN2 may not be formed on the second light emitting layer EL2.

According to this embodiment, the optical opening OPN2 may not be located in the second sub-pixel SPX2 in which the first side S1 and the second side S2 have substantially the same length. Accordingly, light provided from the second sub-pixel SPX2 may have similar color coordinates for each of observed directions, and a location (e.g., placement) of the second protective layer PVX2 may not be provided. In this case, a front surface light output efficiency for the second sub-pixel SPX2 may be further secured and/or improved.

A display device DD according to an embodiment is applicable to various types of electronic devices 10. In an embodiment, an electronic device 10 includes the above-described display device DD and may further include other modules or devices having additional functions in addition to the display device DD.

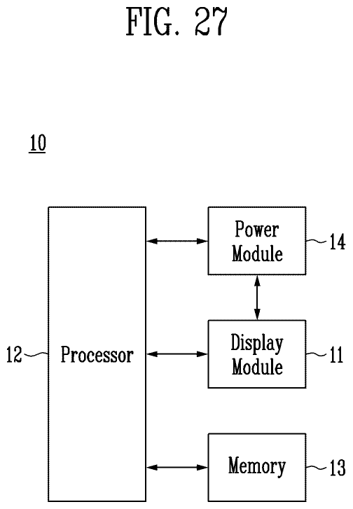

FIG. 27 is a block diagram of an electronic device according to an embodiment. Referring to FIG. 27, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply (power) module, such as a power adapter or a battery device, and a power conversion module. The power conversion module converts power supplied by the power supply module and generates power to operate the electronic device 10.

At least one of the above-described components of the electronic device 10 may be included in the display device DD according to embodiments as described above. In addition, in terms of functionality, some of the individual modules included in one module may be included in the display device DD and others may be provided separately from the display device DD. For example, the display module 11 is included in the display device DD, whereas the processor 12, the memory 13, and the power module 14 are not included in the display device DD and are instead provided separately in the electronic device 10.

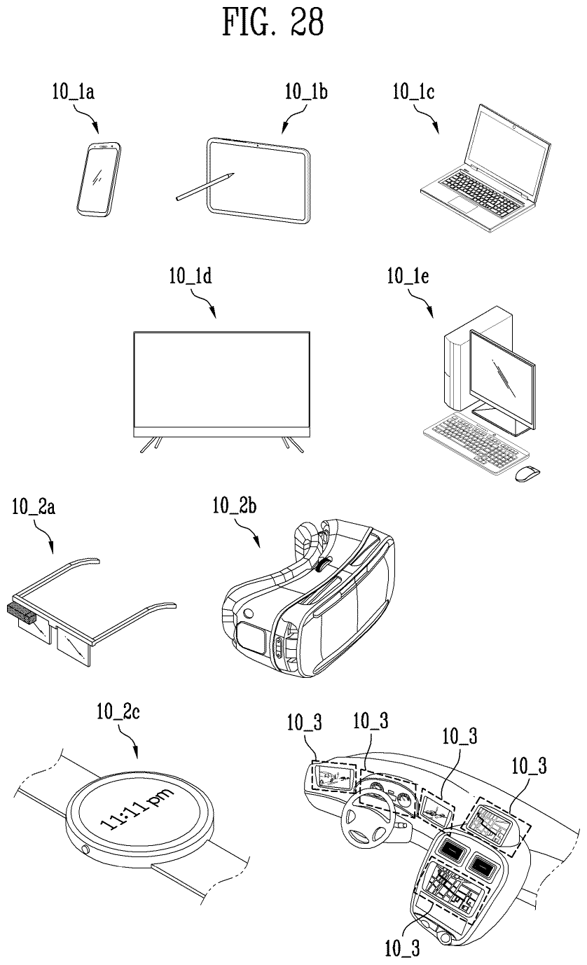

FIG. 28 shows schematic views of various embodiments of an electronic device.

Referring to FIG. 28, various types of electronic devices to which embodiments of a display device DD are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

As described above, although the disclosure has been described with reference to the example embodiments above, those skilled in the art and/or those having a common knowledge in the art will understand that the disclosure may be variously modified and changed without departing from the spirit and technical area of the disclosure described in the claims which will be described in more detail herein below.

Therefore, the technical scope of the disclosure should not be limited to the contents described in the detailed description of the specification, but should be defined by the claims and their equivalents.

What is claimed is:

1. A display device comprising:
a display layer comprising a light emitting element, the light emitting element comprising
a first electrode,
a second electrode, and
a light emitting layer electrically connected to the first electrode and the second electrode; and
a sensor layer on the display layer, the sensor layer comprising
a conductive pattern layer,
a protective layer at least partially on the conductive pattern layer, and
an optical adhesive layer on the protective layer,
the optical adhesive layer forming an interface with the protective layer, and comprising an optical adhesive material,
wherein the protective layer comprises a first protective layer covering the conductive pattern layer and a second protective layer spaced from the first protective layer and at least partially overlapping the light emitting layer in a plan view, and
the second protective layer comprises an edge portion which does not overlap the light emitting layer in a plan view.

2. The display device of claim 1, comprising:
a sub-pixel area in which light of a color is provided and a non-sub-pixel area,
wherein the second protective layer is in the sub-pixel area, and at least a portion of the first protective layer is in the non-sub-pixel area,
the sub-pixel area comprises a first sub-pixel area, a second sub-pixel area, and a third sub-pixel area,
the light emitting layer comprises a first light emitting layer in the first sub-pixel area, a second light emitting layer in the second sub-pixel area, and a third light emitting layer in the third sub-pixel area,
the second protective layer comprises a (2-1)-th protective layer in the first sub-pixel area, a (2-2)-th protective layer in the second sub-pixel area, and a (2-3)-th protective layer in the third sub-pixel area,
the edge portion comprises a first edge portion in the first sub-pixel area, a second edge portion in the second sub-pixel area, and a third edge portion in the third sub-pixel area, and
the protective layer has a refractive index greater than a refractive index of the optical adhesive layer.

3. The display device of claim 2, wherein the refractive index of the protective layer is in a range of about 1.50 to about 1.58, and
the refractive index of the optical adhesive layer is in a range of about 1.46 to about 1.50.

4. The display device of claim 2, wherein a side surface of the second protective layer forms a tapered surface in a forward direction, and
the (2-1)-th protective layer, the (2-2)-th protective layer, and the (2-3)-th protective layer have shapes different from each other.

5. The display device of claim 2, wherein the first light emitting layer comprises a first side extending in a first direction and a second side extending in a second direction different from the first direction,
the first side of the first light emitting layer is longer than the second side of the first light emitting layer,
the first edge portion is adjacent to the first side of the first light emitting layer in the second direction, and
the first light emitting layer protrudes in the first direction with respect to the (2-1)-th protective layer in a plan view.

6. The display device of claim 5, wherein the third light emitting layer comprises a first side extending in the first direction and a second side extending in the second direction,
the second side of the third light emitting layer is longer than the first side of the third light emitting layer,
the third edge portion is adjacent to the second side of the third light emitting layer in the first direction, and
the third light emitting layer protrudes in the second direction with respect to the (2-3)-th protective layer in a plan view.

7. The display device of claim 6, wherein the second light emitting layer comprises a first side extending in the first direction and a second side extending in the second direction,
the first side of the second light emitting layer and the second side of the second light emitting layer have a same length,
a portion of the second edge portion is adjacent to the first side of the second light emitting layer along the second direction, and another portion of the second edge portion is adjacent to the second side of the second light emitting layer along the first direction, and
the second light emitting layer is entirely covered by the (2-2)-th protective layer in a plan view.

8. The display device of claim 2, wherein each of the first light emitting layer, the second light emitting layer, and the third light emitting layer comprises a first side extending in a first direction and a second side extending in a second direction different from the first direction,
each of the (2-1)-th protective layer and the (2-3)-th protective layer comprises a plurality of portions, and
the (2-2)-th protective layer is a single piece.

9. The display device of claim 8, wherein the (2-1)-th protective layer comprises a first portion and a second portion spaced from each other with a separation area between the first portion and the second portion,
the first portion and the second portion of the (2-1)-th protective layer are not provided on at least a portion of the first side of the first light emitting layer,
the (2-3)-th protective layer comprises a first portion and a second portion spaced from each other with a separation area between the first portion and the second portion, and
the first portion and the second portion of the (2-3)-th protective layer are not provided on at least a portion of the second side of the third light emitting layer.

10. The display device of claim 9, wherein the separation area of the (2-1)-th protective layer extends in the second direction, and the separation area of the (2-3)-th protective layer extends in the first direction.

11. The display device of claim 9, wherein the separation area for the (2-1)-th protective layer extends in a first diagonal direction between the first direction and the second direction, and
the separation area for the (2-3)-th protective layer extends in a second diagonal direction between the first direction and the second direction.

12. The display device of claim 2, wherein the third sub-pixel area is spaced from the first sub-pixel area and the second sub-pixel area in a first direction, and
the first sub-pixel area and the second sub-pixel area are spaced from each other in a second direction different from the first direction.

13. The display device of claim 1, comprising:
a sub-pixel area in which light of a color is provided and a non-sub-pixel area,
wherein the second protective layer is in the sub-pixel area, and at least a portion of the first protective layer is in the non-sub-pixel area,
the sub-pixel area comprises a first sub-pixel area to emit red light, a second sub-pixel area to emit green light, and a third sub-pixel area to emit blue light,
the light emitting layer comprises a first light emitting layer in the first sub-pixel area, a second light emitting layer in the second sub-pixel area, and a third light emitting layer in the third sub-pixel area,
the second light emitting layer comprises a first side and a second side having a same length, and
the second protective layer is in the first sub-pixel area and the third sub-pixel area, and is not in the second sub-pixel area.

14. The display device of claim 1, wherein the conductive pattern layer comprises a first conductive pattern layer and a second conductive pattern layer in different layers, and an insulating layer is between the first conductive pattern layer and the second conductive pattern layer,
the first protective layer directly covers the second conductive pattern layer, and the second protective layer does not directly cover the second conductive pattern layer,
the display layer comprises an encapsulation layer covering the light emitting element,
the sensor layer comprises a sensor base layer where the conductive pattern layer is provided, and
the sensor base layer is directly on the encapsulation layer.

15. A display device comprising:
a display layer comprising a light emitting element comprising a first electrode, a second electrode, and a light emitting layer electrically connected to the first electrode and the second electrode; and
a sensor layer comprising a conductive pattern layer, a protective layer at least partially on the conductive pattern layer, an intermediate layer on the protective layer and forming an interface with the protective layer, and an optical adhesive layer on the intermediate layer and comprising an optical adhesive material,
wherein the protective layer comprises an optical opening at least partially overlapping the light emitting layer in a plan view,
at least a portion of the intermediate layer is in the optical opening, and
at least a portion of the optical opening does not overlap the light emitting layer in a plan view.

16. The display device of claim 15, comprising:
a sub-pixel area in which light of a color is provided and a non-sub-pixel area,
wherein at least a portion of the optical opening is in the sub-pixel area, at least a portion of the protective layer is in the non-sub-pixel area,
the sub-pixel area comprises a first sub-pixel area, a second sub-pixel area, and a third sub-pixel area,
the light emitting layer comprises a first light emitting layer in the first sub-pixel area, a second light emitting layer in the second sub-pixel area, and a third light emitting layer in the third sub-pixel area,
the optical opening comprises a first optical opening in the first sub-pixel area, a second optical opening in the second sub-pixel area, and a third optical opening in the third sub-pixel area, and
the intermediate layer has a refractive index greater than a refractive index of the protective layer.

17. The display device of claim 16, wherein the first optical opening, the second optical opening, and the third optical opening have shapes different from each other.

18. The display device of claim 16, wherein each of the first light emitting layer, the second light emitting layer, and the third light emitting layer comprises a first side extending in a first direction and a second side extending in a second direction different from the first direction,
the first side of the first light emitting layer is longer than the second side of the first light emitting layer,
the first side of the second light emitting layer and the second side of the second light emitting layer have a same length,
the second side of the third light emitting layer is longer than the first side of the third light emitting layer,
at least a portion of the first optical opening which does not overlap the first light emitting layer is adjacent to the first side of the first light emitting layer in the second direction in a plan view,
the second light emitting layer is entirely covered by the second optical opening in a plan view, and
at least a portion of the third optical opening which does not overlap the third light emitting layer is adjacent to the second side of the third light emitting layer in the first direction in a plan view.

19. The display device of claim 16, wherein each of the first light emitting layer, the second light emitting layer, and the third light emitting layer comprises a first side extending in a first direction and a second side extending in a second direction different from the first direction,
the first optical opening comprises a first optical portion and a second optical portion spaced from each other with a separation area between the first optical portion and the second optical portion,
the separation area for the first optical opening extends in a diagonal direction between the first direction and the second direction, or in the second direction,
the third optical opening comprises a first optical portion, a second optical portion, and a third optical portion spaced from each other with a separation area between the first optical portion, the second optical portion, and the third optical portion, and
the separation area for the third optical opening extends in another diagonal direction between the first direction and the second direction, or in the first direction.

20. An electronic device comprising:
a processor;
a display device configured to display an image; and
a power module configured to supply power to the display device,
wherein the display device comprises:
a display layer comprising a light emitting element, the light emitting element comprising
a first electrode,
a second electrode, and
a light emitting layer electrically connected to the first electrode and the second electrode; and
a sensor layer on the display layer, the sensor layer comprising
a conductive pattern layer,
a protective layer at least partially on the conductive pattern layer, and
an optical adhesive layer on the protective layer,
the optical adhesive layer forming an interface with the protective layer and comprising an optical adhesive material,
the protective layer comprises a first protective layer covering the conductive pattern layer and a second protective layer spaced from the first protective layer and at least partially overlapping the light emitting layer in a plan view, and
the second protective layer comprises an edge portion which does not overlap the light emitting layer in a plan view.
